(19) United States
(12) Patent Application Publication
(10) Pub. No.: US 2026/0362687 A1
(43) Pub. Date: Nov. 12, 2026

(54) SEMICONDUCTOR DEVICES INCLUDING VERTICAL CHANNEL STRUCTURE AND DATA STORAGE SYSTEMS INCLUDING SAME

(71) Applicant: SAMSUNG ELECTRONICS CO., LTD., Suwon-si (KR)

(72) Inventors: Byungchul LEE, Suwon-si (KR); Jiho SONG, Suwon-si (KR); Joonyoung KWON, Suwon-si (KR); Junhyoung KIM, Suwon-si (KR); Jiyoung KIM, Suwon-si (KR); Sukkang SUNG, Suwon-si (KR); Cheonan LEE, Suwon-si (KR); Ikhyung JOO, Suwon-si (KR)

(73) Assignee: SAMSUNG ELECTRONICS CO., LTD., Suwon-si (KR)

(21) Appl. No.: 19/402,144

(22) Filed: Nov. 26, 2025

(30) Foreign Application Priority Data
May 12, 2025 (KR) 10-2025-0061346

(51) Int. Cl. H10B 41/27; H10B 41/30; H10B 43/27; H10B 43/30; H10B 80/00; H10D 80/30; H10W 90/00

(52) U.S. Cl. CPC H10B 41/27; H10B 41/30; H10B 43/27; H10B 43/30; H10B 80/00; H10D 80/30; H10W 90/00

(57) ABSTRACT

A semiconductor device includes gate electrodes stacked and spaced apart from each other; interlayer insulating layers alternately stacked with the gate electrodes; channel structures penetrating through the gate electrodes; gate contact structures penetrating through at least a portion of the gate electrodes; first channel connection patterns below lower ends of the gate contact structures; vertical channel structures penetrating through a first gate electrode below the first channel connection patterns; channel connection pads below the vertical channel structures; upper contact structures penetrating through the first channel connection pattern, and connected to the gate contact structure; and the vertical channel structures may include first and second vertical channel structures, first ends of the first and second vertical channel structures are connected to the first channel connection pattern, and second ends of the first vertical channel structures may be connected to the upper contact structure.

### CROSS-REFERENCE TO RELATED APPLICATIONS

This application claims benefit of priority to Korean Patent Application No. 10-2025-0061346 filed on May 12, 2025, in the Korean Intellectual Property Office, the disclosure of which is incorporated herein by reference in its entirety.

### BACKGROUND

The present disclosure relates to semiconductor devices and data storage systems including the same.

In a data storage system requiring data storage, a semiconductor device capable of storing a large amount of data is required. Accordingly, a method of increasing the data storage capacity of a semiconductor device has been researched. For example, as one method of increasing the data storage capacity of a semiconductor device, a semiconductor device including memory cells arranged three-dimensionally, instead of memory cells two-dimensionally arranged, has been proposed.

### SUMMARY

An aspect of the present disclosure is to provide a semiconductor device having improved device characteristics and a miniaturized chip size.

An aspect of the present disclosure is to provide a data storage system including a semiconductor device having improved device characteristics and a miniaturized chip size.

A semiconductor device according to example embodiments may include: a first semiconductor structure including a substrate, circuit elements disposed on the substrate, a first interconnection structure on the circuit elements, and first bonding pads on the first interconnection structure; and a second semiconductor structure disposed on the first semiconductor structure and including a first region and a second region disposed in one end of the first region in the first direction, and the second semiconductor structure may include: gate electrodes stacked and spaced apart from each other in a second direction, perpendicular to an upper surface of the substrate; interlayer insulating layers alternately stacked with the gate electrodes; channel structures penetrating through at least a portion of the gate electrodes in the first region and extending in the second direction, each of which including a channel layer; gate contact structures penetrating through at least a portion of the gate electrodes in the second region and extending in the second direction, each of which is electrically connected to a portion of the gate electrodes; a common source layer covering upper ends of the channel structures and in contact with the channel layer; first channel connection patterns disposed below lower ends of the gate contact structures in the second region; vertical channel structures penetrating through the first gate electrode disposed below a first channel connection patterns, among the gate electrodes, and extending in the second direction; channel connection pads disposed below the vertical channel structures; upper contact structures penetrating through the first gate electrode and the first channel connection pattern, the upper contact structures extending in the second direction, and connected to the gate contact structure; second interconnection structures including cell interconnection lines electrically connected to the channel structures or the channel connection pads, the second interconnection structures disposed below lower ends of the channel structures and the channel connection pads; and second bonding pads disposed below the second interconnection structure and connected to the first bonding pads, and the vertical channel structures may include first vertical channel structures in which first ends thereof in the second direction are connected to the first channel connection pattern, and second vertical channel structures connected to the first vertical channel structures through the first channel connection pattern, and second ends of the first vertical channel structures, which are an opposite end of the first ends in the second direction, may be connected to the upper contact structure.

A semiconductor device according to example embodiments may include: gate electrodes stacked and spaced apart from each other in a first direction, perpendicular to an upper surface of a substrate; channel structures penetrating through the gate electrodes and extending in the first direction, and respectively including a channel layer; gate contact plugs extending in the first direction and electrically connected to the gate electrodes, respectively; vertical channel structures penetrating through the first gate electrode disposed below a lower end of the gate contact plug among the gate electrodes, and vertical channel structures extending in the first direction, and respectively including a vertical channel layer; channel connection patterns disposed on the first gate electrode and in contact with first ends of the vertical channel structures in the first direction; channel connection pads disposed below the first gate electrode and in contact with second ends of the vertical channel structures in the first direction, the channel connection pads including a first channel connection pad and a second channel connection pad which are spaced apart from each other; and upper contact plugs penetrating through the first gate electrode and extending in the first direction, the upper contact plugs electrically connected to the gate contact plugs, respectively.

A data storage system according to example embodiments may include: a semiconductor storage device including a first semiconductor structure including circuit elements, a second semiconductor structure disposed on the first semiconductor structure, and an input/output pad electrically connected to the circuit elements; and a controller electrically connected to the semiconductor storage device through the input/output pad and configured to control the semiconductor storage device, and the second semiconductor structure may include: gate electrodes stacked and spaced apart from each other in a first direction, perpendicular to an upper surface of the first semiconductor structure; channel structures penetrating through the gate electrodes and extending in the first direction, and respectively including a channel layer; gate contact plugs extending in the first direction and electrically connected to the gate electrodes; vertical channel structures penetrating through a first gate electrode disposed below a lower end of the gate contact plug, among the gate electrodes, and extending in the first direction, and respectively including a vertical channel layer; channel connection patterns disposed on the first gate electrode and in contact with first ends of the vertical channel structures in the first direction; channel connection pads disposed below the first gate electrode and in contact with second ends of the vertical channel structures in the first direction; and upper contact plugs penetrating through the first gate electrode and extending in the first direction, and electrically connected to the gate contact plugs, respectively, wherein each of the vertical channel structures may include a vertical channel buried insulating layer surrounded by the vertical channel layer, a vertical channel dielectric layer surrounding the vertical channel layer, and a vertical channel pad adjacent to the second end of the vertical channel structure and in contact with the vertical channel buried insulating layer.

Transistors including vertical channels may be included in the cell structure, thereby providing a semiconductor device having a miniaturized chip size and improved electrical characteristics and a data storage system including the same.

Advantages and effects of the present application are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan view of a semiconductor device according to example embodiments;

FIGS. 2A and 2B are schematic cross-sectional views of a semiconductor device according to example embodiments;

FIGS. 3A, 3B, 3C, and 3D are partially-enlarged views of a semiconductor device according to example embodiments;

FIGS. 4A, 4B, 4C, and 4D are exploded perspective views and partial plan views illustrating a portion of a semiconductor device according to example embodiments;

FIG. 5 is a partial cross-sectional view illustrating a semiconductor device according to example embodiments;

FIGS. 6A, 6B, 6C, 6D, and 6E are partially-enlarged views illustrating a semiconductor device according to example embodiments;

FIGS. 7A, 7B, 7C, and 7D are cross-sectional views of a semiconductor device according to example embodiments;

FIGS. 8A, 8B, 8C, 8D, 8E, 8F, 8G, 8H, 8I, 8J, 8K, 8L, 8M, 8N, and 8O are schematic cross-sectional views illustrating a method of manufacturing a semiconductor device according to example embodiments;

FIG. 9 is a schematic diagram of a data storage system including a semiconductor device according to example embodiments;

FIG. 10 is a perspective view schematically illustrating a data storage system including a semiconductor device according to an example embodiment; and

FIG. 11 is a cross-sectional view schematically illustrating a semiconductor package according to an example embodiment.

### DETAILED DESCRIPTION

Hereinafter, example embodiments of the present disclosure will be described with reference to the accompanying drawings.

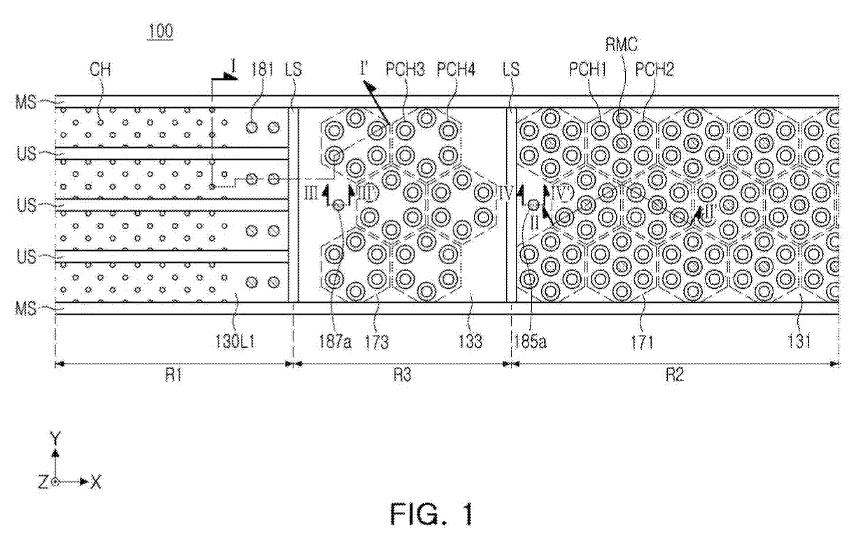

FIG. 1 is a schematic plan view of a semiconductor device according to example embodiments.

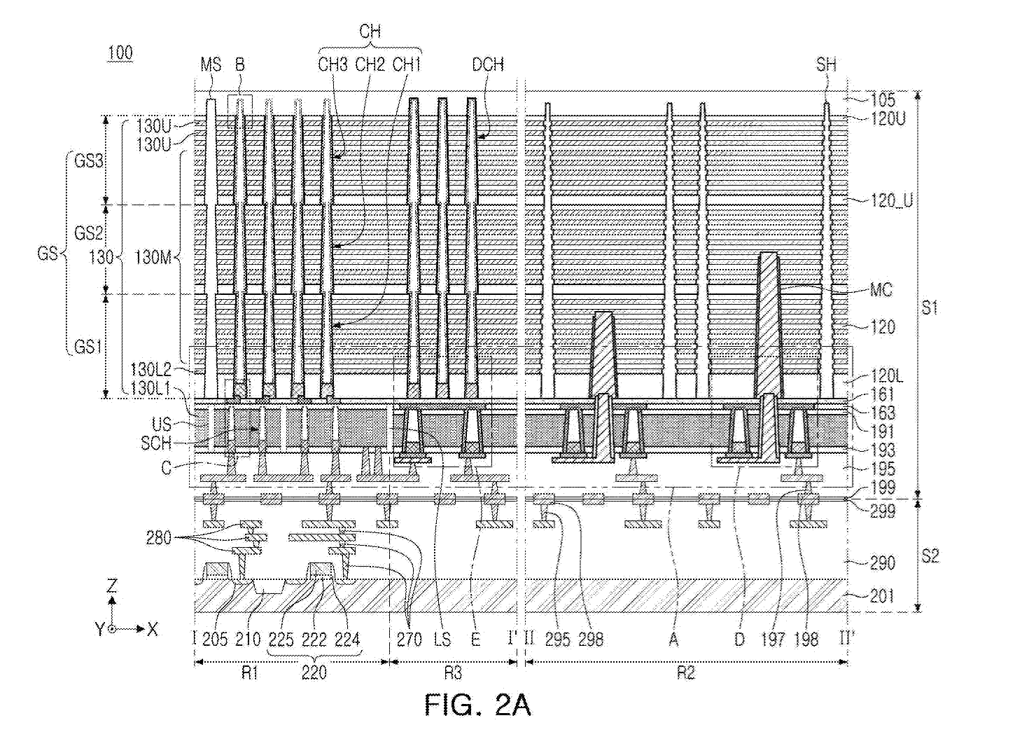

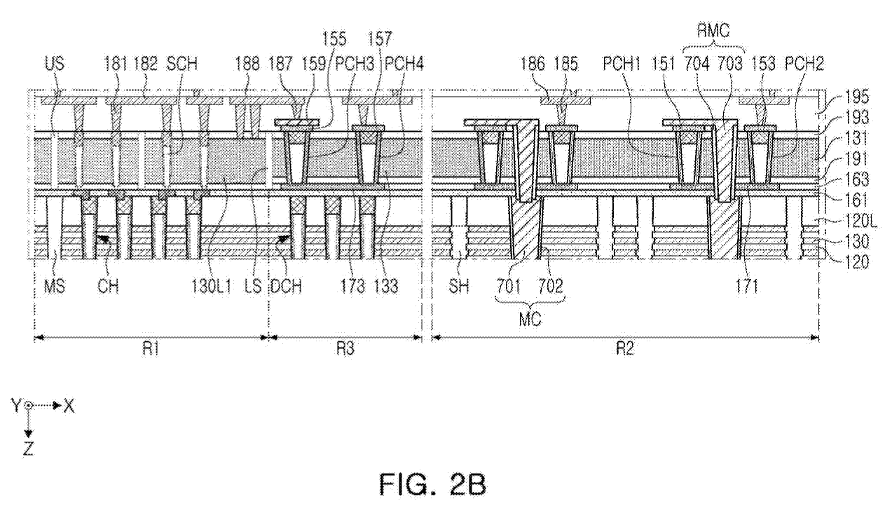

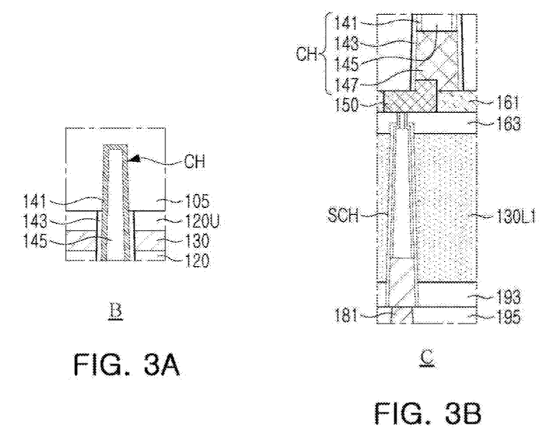

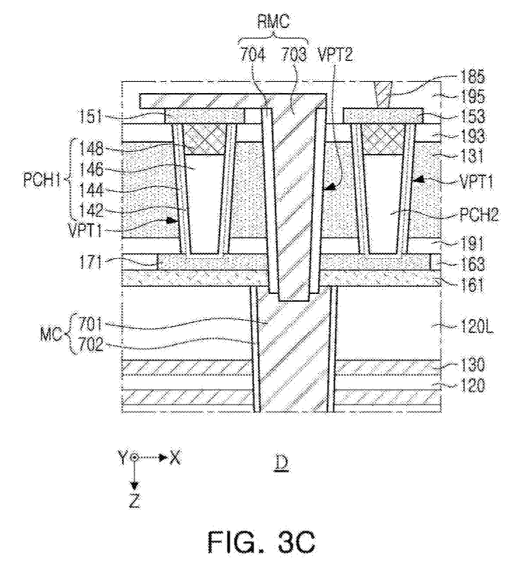

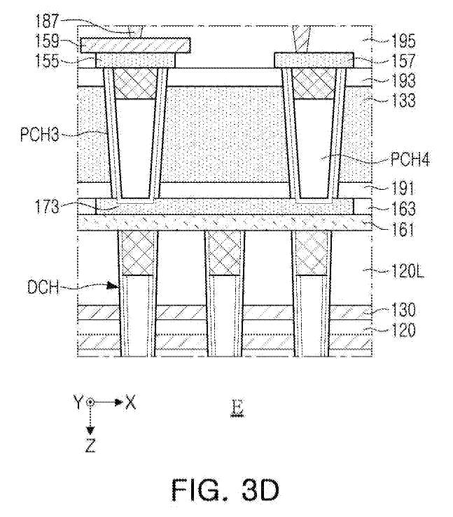

FIGS. 2A and 2B are schematic cross-sectional views of a semiconductor device according to example embodiments. FIGS. 3A-3D are partially-enlarged views of a semiconductor device according to example embodiments. FIG. 2A illustrates a cross-section along the cutting lines I-I' and II-II' of FIG. 1. FIG. 2B is an enlarged view of region 'A' of FIG. 2A, which illustrates an upside-down state of region 'A' of FIG. 2A. FIGS. 3A-3D are enlarged views of region 'B', region 'C', region 'D' and region 'E' of FIG. 2A, respectively, and FIGS. 3C and 3D also illustrate regions 'C' and 'D' of FIG. 2A, respectively, upside-down.

Referring to FIGS. 1, 2A, 2B, 3A, 3B, 3C and 3D, a semiconductor device 100 includes first and second semiconductor structures S1 and S2 which are bonded vertically. For example, the first semiconductor structure S1 may include a peripheral circuit region, and the second semiconductor structure S2 may include a memory cell region. In some example embodiments, the second semiconductor structure S2 may be disposed below the first semiconductor structure S1. FIG. 1 illustrates a plan view of some components of the second semiconductor structure S2 on a level of a first lower gate electrode 130L1.

The first semiconductor structure S1 may include a substrate 201, source/drain regions 205 and element isolation layers 210 within the substrate 201, circuit elements 220 disposed on the substrate 201, a peripheral region insulating layer 290, circuit contact plugs 270, circuit interconnection lines 280, first bonding vias 295, first bonding pads 298, and a first bonding insulating layer 299.

The substrate 201 may have an upper surface extending in an X-direction and a Y-direction. An active region may be defined in the substrate 201 by the element isolation layers 210. Source/drain regions 205 including impurities may be disposed in a portion of the active region. The substrate 201 may include a semiconductor material, such as a group IV semiconductor, a group III-V compound semiconductor, or a group II-VI compound semiconductor. The substrate 201 may be provided as a bulk wafer or an epitaxial layer.

The circuit elements 220 may include planar transistors. Each of the circuit elements 220 may include a circuit channel dielectric layer 222, a spacer layer 224, and a circuit gate electrode 225. The source/drain regions 205 may be disposed as source/drain regions within the substrate 201 on both sides of the circuit gate electrode 225. In the drawing, the circuit elements 220 are illustrated as being in a first region R1, but the present disclosure is not limited thereto. According to an example embodiment, a semiconductor device 100 may be configured such that some circuit elements 220 disposed in a second region R2 and a third region R3 of a first semiconductor structure S1 may be disposed in the second semiconductor structure S2, and some circuit elements 220 may also be disposed in the second region R2 and the third region R3. The semiconductor device 100 may have a reduced number of circuit elements 220 disposed in the first semiconductor structure S1, thereby miniaturizing a chip size.

The peripheral region insulating layer 290 may be disposed to cover the circuit elements 220 on an upper surface of the substrate 201. The peripheral region insulating layer 290 may include a plurality of insulating layers formed in different process operations. The peripheral region insulating layer 290 may be formed of an insulating material.

The circuit contact plugs 270 and the circuit interconnection lines 280 may form an interconnection structure electrically connected to the circuit elements 220 and the source/drain regions 205. The circuit contact plugs 270 may have a cylindrical shape, and the circuit interconnection lines 280 may have a line shape. An electrical signal may be applied to the circuit element 220 by the circuit contact plugs 270 and the circuit interconnection lines 280. In a region not illustrated in the drawing, the circuit gate electrode 225 may be connected to the circuit contact plugs 270. The circuit interconnection lines 280 may be connected to the circuit contact plugs 270 and may be disposed in a plurality of layers. The circuit contact plugs 270 and the circuit interconnection lines 280 may include a conductive material. For example, each of the circuit contact plugs 270 and the circuit interconnection lines 280 may include tungsten (W), copper (Cu) and aluminum (Al), and each of the configurations may further include a diffusion barrier. In example embodiments, the number of layers of the circuit contact plugs 270 and the circuit interconnection lines 280 may be variously changed.

The first bonding vias 295, the first bonding pads 298, and the first bonding insulating layer 299 may be included in the first bonding structure and may be disposed on uppermost circuit interconnection lines 280. The first bonding vias 295 may have a cylindrical shape, and the first bonding pads 298 may have a pad shape having a circular shape on a plane or a relatively short line shape. Upper surfaces of the first bonding pads 298 may form a portion of an upper surface of the first semiconductor structure S1. The first bonding vias 295 and the first bonding pads 298 may provide electrical connection paths with the second semiconductor structure S2. In example embodiments, some of the first bonding pads 298 may not be connected to the circuit interconnection lines 280 and may be disposed only for bonding. The first bonding vias 295 and the first bonding pads 298 may include a conductive material, and may include, for example, copper (Cu).

The first bonding insulating layer 299 may be disposed on an upper surface of the peripheral region insulating layer 290 to a predetermined thickness. The first bonding insulating layer 299 may be a layer for dielectric-to-dielectric bonding with a second bonding insulating layer 199 of the second semiconductor structure S2. The first bonding insulating layer 299 may also function as a diffusion barrier layer of the first bonding pads 298, and may include, for example, at least one of SiO, SiN, SiCN, SiOC, SiON or SiOCN.

The second semiconductor structure S2 may have first to third regions R1, R2 and R3. The second semiconductor structure S2 may include the first region R1, the second region R2 disposed in one end of at least one direction of the first region R1, for example, the X-direction as a first direction, and a third region R3 disposed between the first region R1 and the second region R2.

The second semiconductor structure S2 may include: gate electrodes 130 vertically stacked to form a gate structure GS, interlayer insulating layers 120 alternately stacked with the gate electrodes 130 to form the gate structure GS, channel structures CH disposed to penetrate through the gate structure GS in the first region R1, gate contact structures MC electrically connected to at least some of the gate electrodes 130 in the second region R2 and extending vertically, first to fourth vertical channel structures PCH1, PCH2, PCH3 and PCH4 disposed to penetrate through some of the gate electrodes 131 and 133 in the second region R2 and/or the third region R3, string channel structures SCH disposed to penetrate through some of the gate electrodes 130 in the first region R1, and channel connection patterns 171 and 173 and channel connection pads 151, 153, 157 and 159 connected to first to fourth vertical channel structures PCH1, PCH2, PCH3 and PCH4.

The second semiconductor structure S2 may include a common source layer 105 covering upper ends of the channel structures CH, first separation regions MS extending through the gate structure GS, and second and third separation regions US and LS penetrating through portions of gate electrodes 130 disposed in a lower portion, among the gate electrodes 130. The second semiconductor structure S2 may further include first to third cell contact plugs 181, 185 and 187 and first to third cell interconnection lines 182, 186 and 188, as a second interconnection structure, below the channel structures. The second semiconductor structure S2 may further include second bonding vias 197, second bonding pads 198, and a second bonding insulating layer 199, as a second bonding structure.

In the second semiconductor structure S2, the first region R1 may be a region in which the gate electrodes 130 are vertically stacked and channel structures CH are disposed, and may be a region in which memory cells are disposed. The second region R2 may be a region in which the gate contact structures MC connected to at least one of the gate electrodes 130 are disposed, and may correspond to a region for electrically connecting the memory cells to the first semiconductor structure S1. The third region R3 may be a region in which dummy channel structures DCH formed to penetrate through the gate electrodes 130 are disposed. Additionally, the second semiconductor structure S2 may include the vertical channel structures PCH1, PCH2, PCH3 and PCH4 disposed in the second region R2 and/or the third region R3, and the circuit elements of the first semiconductor structure S1 may be electrically connected to the gate electrodes 130 of the second semiconductor structure S2. The second region R2 and the third region R3 may be regions in which transistors including channel regions formed by a plurality of first to fourth vertical channel structures PCH1, PCH2, PCH3 and PCH4 are formed.

The gate electrodes 130 may be stacked so as to be spaced apart from each other in a direction, perpendicular to an upper surface of the substrate 201, for example, in a Z-direction, and may form a gate structure GS together with the interlayer insulating layers 120. The second semiconductor structure S2 may include a gate structure GS including at least one or more gate stack structures GS1, GS2 and GS3. For example, the gate structure GS may include first to third gate stack structures GS1, GS2 and GS3 that are vertically stacked. However, according to example embodiments, the gate structure GS may be formed of a single gate stack structure or may include three or more gate stack structures. The number of gate electrodes 130 included in each of the first to third gate stack structures GS1, GS2 and GS3 may be the same or different.

The gate electrodes 130 may include lower gate electrodes 130L and 130L1 included in gates of string select transistors, memory gate electrodes 130M of a plurality of memory cells, and upper gate electrodes 130U included in a gate of a ground select transistor. The number of memory gate electrodes 130M of memory cells may be determined according to the capacity of the semiconductor device 100. In example embodiments, the number of upper and lower gate electrodes 130U, 130L and 130L1 may be 1 to 4 or more, respectively, and may have the same or different structure as the memory gate electrodes 130M. Additionally, in example embodiments, the gate electrodes 130 may further include a gate electrode 130 disposed adjacently to the upper gate electrodes 130U and/or the lower gate electrodes 130L and 130L1 and forming an erase transistor used for an erase operation using a gate induced drain leakage (GIDL) phenomenon. Additionally, some of the gate electrodes 130, for example, the memory gate electrodes 130M adjacent to the upper or lower gate electrodes 130U, 130L and 130L1, may be dummy gate electrodes. In an example embodiment, the second semiconductor structure S2 may be configured such that the first lower gate electrode 130L1 disposed in a lowermost portion in the first region R1, among the gate electrodes 130, may be disposed to have a relatively thicker thickness than those of the other gate electrodes 130. Additionally, the first gate electrode 131 and the second gate electrode 133 disposed in the second region R2 and the third region R3, among the gate electrodes 130, respectively, may also be disposed to have a relatively thicker thickness than those of the other gate electrodes 130.

As illustrated in FIG. 1, the gate electrodes 130 may be separated from each other in the Y-direction by first separation regions MS extending continuously in the first region R1, the second region R2, and the third region R3. The gate electrodes 130 between a pair of first separation regions MS may form one memory block, but the range of the memory block is not limited thereto. Some of the gate electrodes 130, for example, the memory gate electrodes 130M, may form one layer each within one memory block.

The gate electrodes 130 may include a metal material, such as tungsten (W). In some example embodiments, the gate electrodes 130 may include polycrystalline silicon or a metal silicide material. For example, among the gate electrodes 130, the first lower gate electrode 130L1, the first gate electrode 131 and the second gate electrode 133 may include polycrystalline silicon, and the other gate electrodes 130 may include a metal material. In example embodiments, the gate electrodes 130 may further include a diffusion barrier, and for example, the diffusion barrier may include tungsten oxide (WN), tantalum nitride (TaN), titanium nitride (TiN), or combinations thereof.

The interlayer insulating layers 120 may be disposed alternately with the gate electrodes 130. The interlayer insulating layers 120 may be spaced apart from each other in a direction, perpendicular to the upper surface of the substrate 201 and may be disposed to extend in the X-direction, similarly to the gate electrodes 130. In each of the first to third gate stacked structures GS1, GS2 and GS3 of the gate structure GS, at least some of the interlayer insulating layers 120 may have different thicknesses. For example, a lowermost interlayer insulating layer 120L, among the interlayer insulating layers 120, may be relatively thick. Additionally, a lower interlayer insulating layers 120_U in each of the first to third gate stacked structures GS1, GS2 and GS3 may also be relatively thick. However, the relative thicknesses of the interlayer insulating layers 120 may be variously modified in example embodiments. The interlayer insulating layers 120 may include an insulating material such as silicon oxide or silicon nitride.

The channel structures CH may extend in the Z-direction through the gate electrodes 130 except for the first lower gate electrode 130L1. Each of the channel structures CH may form one memory cell string, and may be spaced apart from each other in rows and columns in the first region R1. The channel structures CH may be disposed to form a grid pattern in an X-Y plane or may be disposed in a zigzag shape in one direction. The channel structures CH may have a pillar shape and may include regions having inclined side surfaces that become wider toward the substrate 201 depending on an aspect ratio.

As illustrated in FIG. 2A, each of the channel structures CH may include first to third channel portions CH1, CH2 and CH3 which are vertically stacked. The first to third channel portions CH1, CH2 and CH3 may penetrate through the gate stacked structures GS1, GS2 and GS3 of the gate structure GS, respectively. The channel structure CH may have a form in which the first channel portion CH1 is connected to the second channel portion CH2 in an upper portion, and the second channel portion CH2 is connected to the third channel portion CH3 in the upper portion. Each of the first to third channel portions CH1, CH2 and CH3 may have an inclined side surface so that a width thereof increases toward the substrate 201. The first to third channel portions CH1, CH2 and CH3 may have a form in which a width of an upper surface of the channel portion disposed in a lower portion is smaller than a width of a lower surface of the channel portion disposed in an upper portion in a region in which the first to third channel portions CH1, CH2 and CH3 are connected to each other or at an interface thereof. The channel structure CH may have a width that is discontinuously changed at an interface between the first to third channel portions CH1, CH2 and CH3 and may have bent portions due to the difference in width. However, according to example embodiments, the number of channel portions stacked in the Z-direction in the channel structure CH may be variously changed.

Lowermost ends of the channel structures CH may be aligned with a lower surface of the lowermost interlayer insulating layer 120L. Uppermost ends of the channel structures CH may protrude onto an uppermost interlayer insulating layer 120U.

As illustrated in FIGS. 3A and 3B, each of the channel structures CH may include a channel layer 141, a channel dielectric layer 143, a channel buried insulating layer 145, and a channel pad 147, which are disposed within a channel hole. The channel layer 141, the channel dielectric layer 143, and the channel buried insulating layer 145 may be connected to each other between the first to third channel portions CH1, CH2 and CH3.

The channel layer 141 may be formed in an annular shape surrounding the internal channel buried insulating layer 145. However, the present disclosure is not limited thereto, and the channel layer 141 may have a columnar shape such as a cylinder or a prism without the channel buried insulating layer 145 according to an example embodiment. The channel layer 141 may include a semiconductor material such as polycrystalline silicon or single-crystal silicon.

The channel dielectric layer 143 may be disposed between the gate electrodes 130 and the channel layer 141. Although not specifically illustrated, the channel dielectric layer 143 may include a tunneling layer, a charge storage layer, and a blocking layer sequentially stacked from the channel layer 141. The tunneling layer may tunnel charges into the charge storage layer, and may include, for example, silicon oxide, silicon nitride, silicon oxynitride, or combinations thereof. The charge storage layer may be a charge trap layer or a floating gate conductive layer. The blocking layer may include silicon oxide, silicon nitride, silicon oxynitride, a high-k dielectric material, or combinations thereof. In example embodiments, at least a portion of the channel dielectric layer 143 may extend horizontally along the gate electrodes 130.

The channel pad 147 may be disposed only in a lower end of the first channel portion CH1 in a lowermost portion. The channel pad 147 may include, for example, doped polycrystalline silicon.

An upper end of the third channel portion CH3 in an uppermost portion of the channel structure CH may be covered with a common source layer 105. The channel dielectric layer 143 may be removed within the common source layer 105 to expose the channel layer 141, and the exposed channel layer 141 may be in contact with the common source layer 105.

The common source layer 105 may extend horizontally in upper ends of the channel structures CH. The common source layer 105 may have a structure covering upper ends of the channel structures CH with, for example, a predetermined thickness. However, the present disclosure is not limited thereto, and according to an example embodiment, the common source layer 105 may have a curve along the upper ends of the channel structures CH. The common source layer 105 may be in contact with and electrically connected to the exposed channel layers 141 of the channel structures CH protruding onto the uppermost interlayer insulating layer 120U, among the interlayer insulating layers 120. The common source layer 105 may function as a common source line of the semiconductor device 100. The common source layer 105 may extend from the first region R1 to the second region R2, but the present disclosure is not limited thereto and the common source layer 105 may be disposed only in the first region R1.

The common source layer 105 may include a conductive material. For example, the common source layer 105 may include polycrystalline silicon and/or a metal material. In some example embodiments, the shape of the common source layer 105 and the number of conductive layers included in the common source layer may be variously changed.

A first horizontal insulating layer 161 and a second horizontal insulating layer 163 may extend horizontally in lower ends of the channel structures CH, respectively. The first horizontal insulating layer 161 and the second horizontal insulating layer 163 may extend horizontally in the first region R1, the second region R2, and the third region R3, respectively, and may be disposed between the first lower gate electrode 130L1, among the gate electrodes 130, and the lowermost interlayer insulating layer 120L, in the first region R1. Each of the first horizontal insulating layer 161 and the second horizontal insulating layer 163 may be disposed between the first gate electrode 131 and the second gate electrode 133 and the lowermost interlayer insulating layer 120L in the second region R2 and the third region R3. Lower ends of the channel structures CH may be coplanar with an upper surface of the first horizontal insulating layer 161. The second horizontal insulating layer 163 may be disposed in a lower end of the first horizontal insulating layer 161. The first horizontal insulating layer 161 and the second horizontal insulating layer 163 may be used as etching stop layers when forming the string channel structures SCH described below, and may also be layers used when forming connection pads 150 of the string channel structures SCH. Additionally, the second horizontal insulating layer 163 may be a layer used when forming the first and second channel connection patterns 171 and 173 formed in the second region R2 and/or the third region R3.

Each of the first horizontal insulating layer 161 and the second horizontal insulating layer 163 may include an insulating material, and may include a material blocking or reducing diffusion of hydrogen (H) as a hydrogen blocking layer. In an example embodiment, each of the first horizontal insulating layer 161 and the second horizontal insulating layer 163 may include a nitride or an oxide, and may include at least one of SiO, SiN, SiON, SiCN or SiOCN. For example, the first horizontal insulating layer 161 may include a nitride, and the second horizontal insulating layer 163 may include an oxide.

The string channel structures SCH may extend in the Z-direction by penetrating through the first lower gate electrode 130L1 and may be connected to the channel structures CH, respectively. The string channel structures SCH may be respectively disposed below the channel structures CH, and may be disposed to be shifted in the horizontal direction from the channel structures CH, but the present disclosure is not limited thereto. The string channel structures SCH may have inclined side surfaces so that widths thereof increase toward the substrate 201.

As illustrated in FIG. 3B, an internal structure of each of the string channel structures SCH may correspond to the channel structures CH, and thus, the stacking patterns of each layer may be identical to each other. The string channel structures SCH may include a string channel layer, a string channel dielectric layer, a string channel buried insulating layer and a string channel pad disposed in a string channel hole penetrating through the first lower gate electrode 130L1. The string channel structures SCH may be connected to the connection pad 150 disposed on a hole penetrating through the first horizontal insulating layer 161, and specifically, the string channel layer may be connected to the connection pad 150 from an upper portion. The string channel structures SCH may be electrically connected to the channel layer 141 of the channel structure CH through the connection pad 150.

The descriptions of each of the channel layer 141, the channel dielectric layer 143, the channel buried insulating layer 145 and the channel pad 147 described above with reference to FIG. 3A may be equally applied to the materials of the string channel layer, the string channel dielectric layer, the string channel buried insulating layer and the string channel pad. The connection pad 150 may include a conductive material, and may include, for example, polycrystalline silicon.

The connection pads 150 may penetrate through the first horizontal insulating layer 161 between the channel structures CH and the string channel structures SCH, so that channel layers 140 of the channel structures CH and the channel layers of the string channel structure SCH may be electrically connected. The connection pads 150 may be formed by removing a portion of the first horizontal insulating layer 161 and may have upper surfaces that are coplanar with the upper surface of the first horizontal insulating layer 161. The connection pads 150 may be disposed in a form in which the channel pads 147 of the channel structure CH are partially recessed. However, a specific arrangement of the connection pads 150 may be variously changed in example embodiments.

The first separation regions MS may be disposed to extend in the X-direction by penetrating through at least a portion of the gate electrodes 130. The first separation regions MS may be disposed parallel to each other, as illustrated in FIG. 1. For example, the first separation regions MS may be disposed parallel to each other by extending in the X-direction and may be spaced apart from each other in the Y-direction. The first separation regions MS may be extended as one along the first region R1, the second region R2, and the third region R3. However, the present disclosure is not limited thereto, and an arrangement form, number, and the like, of the first separation regions MS in example embodiments may be variously changed. In some example embodiments, some of the first separation regions MS may extend only from the first region R1 to a portion of the second region R2, or may be intermittently disposed in the first region R1 and the second region R2.

As illustrated in FIG. 2A, the first separation regions MS may extend in the Z-direction by penetrating through the gate electrodes 130 except for the first lower gate electrode 130L1. A lower end of the first separation region MS may be disposed on the same level as lower ends of the channel structures CH or an upper surface of the first horizontal insulating layer 161. An upper end of the first separation region MS may be disposed on the same level as upper ends of the channel structures CH or on a higher level. For example, a lower end of the first separation region MS may be coplanar with a lower surface of the lowermost interlayer insulating layer 120L, but the present disclosure is not limited thereto.

The first separation region MS may have a shape whose width decreases toward the common source layer 105. A width of the first separation region MS in a lower portion may be greater than a width thereof in an upper portion. For example, the first separation region MS may have a shape corresponding to the channel structures CH, but may have a shape having a width greater than that of the channel structures CH. Accordingly, on least a level of the lower end of the first separation region MS may be the same as a level of the lower ends of the channel structures CH. In this specification, the ‘corresponding shape’ refers to a case in which a shape including an inclination direction and a bent portion is the same or similar, and a size such as a diameter and a height may be identical or different. However, the shape of the first separation region MS is not limited thereto, and according to an example embodiment, the first separation region MS may have a substantially constant inclination side surface so that a width thereof is continuously or continuously reduced, and may not have a bent portion on a side surface thereof. In this case, a shape of the first separation region MS may be different from a shape of the channel structures CH. The first separation region MS may include an insulating material, and may include, for example, silicon oxide, silicon nitride, or silicon oxynitride.

Second separation regions US may extend in the X-direction between the adjacent first separation regions MS, as illustrated in FIG. 1. The second separation regions US may be disposed in the first region R1. Some of the second separation regions US may be disposed on the first separation regions MS. The second separation regions US may penetrate through a first lower gate electrode 130L1 in a lowermost position, among the gate electrodes 130, and the second horizontal insulating layer 163. The second separation regions US may mutually separate the first lower gate electrode 130L1 in the Y-direction in the first region R1. However, the present disclosure is not limited thereto, and may penetrate through several gate electrodes 130 adjacent thereto, including the first lower gate electrode 130L1. The second separation regions US may include an insulating material, and may include, for example, silicon oxide, silicon nitride, or silicon oxynitride.

Third separation regions LS may extend in the Y-direction between different regions R1, R2 and R3 of the second semiconductor structure S2, as illustrated in FIG. 1, and may be disposed between a pair of adjacent first separation regions US. The third separation regions LS may be disposed between the first region R1 and the third region R3, and between the second region R2 and the third region R3. The third separation regions LS may penetrate through lowermost gate electrodes, among the gate electrodes 130, and the second horizontal insulating layer 163, similarly to the second separation regions US. The third separation regions LS may include an insulating material, for example, silicon oxide, silicon nitride, or silicon oxynitride.

A first lower gate electrode 120L1 may be separated from other gate electrodes 131 and 133 disposed in the first region R1, the second region R2 and the third region R3 by the third separation regions LS. The first lower gate electrode 120L1 may be integrally formed over the first region R1, the second region R2 and the third region R3 and then separated into each region R1, R2 and R3 by the first separation regions MS and the third separation regions LS. The first lower gate electrode 130L1 may be disposed in the first region R1, the first gate electrode 131, or a ‘pass gate electrode’, may be disposed in the second region R2, and the second gate electrode 133, or a ‘string gate electrode’, may be disposed in the third region R3. The first lower gate electrode 130L1, the first gate electrode 131 and the second gate electrode 133 may be disposed on substantially the same level, respectively. For example, lower surfaces of the first lower gate electrode 130L1, the first gate electrode 131 and the second gate electrode 133 may be disposed on the same level to form a coplanar surface. However, a first cell region insulating layer 191 may be disposed between the first gate electrode 131 and the second gate electrode 133 and the second horizontal insulating layer 163 in the second region R2 and the third region R3, and upper surfaces of the first gate electrode 131 and the second gate electrode 133 may be disposed on a lower level than that of an upper surface of the first lower gate electrode 130L1. The first gate electrode 131 and the second gate electrode 133 may have a thickness smaller than that of the first lower gate electrode 130L1. However, the present disclosure is not limited thereto, and the first lower gate electrode 130L1, upper and lower surfaces of the first gate electrode 131 and the second gate electrode 133 may be disposed on different levels, respectively. In an example embodiment, the first lower gate electrode 130L1, the first gate electrode 131 and the second gate electrode 133 may have the same thickness.

The dummy channel structures DCH may be disposed in the third region R3. Although not illustrated in FIG. 1, the dummy channel structures DCH may be disposed spaced apart from each other while forming rows and columns in plan view in the third region R3. The dummy channel structures DCH may have a pillar shape penetrating through at least a portion of the gate electrodes 130 and may have a shape corresponding to the channel structures CH. For example, the dummy channel structures DCH may have bent portions corresponding to the first to third channel sections CH1, CH2 and CH3. As illustrated in FIG. 2A, the channel structures CH and the dummy channel structures DCH may have substantially similar structures, but the dummy channel structures DCH may have a structure having a larger diameter than those of the channel structures CH. The dummy channel structures DCH may include a channel layer 141, a channel dielectric layer 143, a channel buried insulating layer 145 and a channel pad 147, and the channel layer 141 may be covered with the channel dielectric layer 143 so that the channel layer 141 of the dummy channel structures DCH does not contact the common source layer 105 in an upper portion, and the channel pad 147 of the dummy channel structures DCH may not be connected to the connection pad 150 and may be in contact with the upper surface of the first horizontal insulating layer 161. However, the present disclosure is not limited thereto. In some example embodiments, the dummy vertical structures DCH may include regions protruding from side surfaces thereof toward the gate electrodes 130, and may have a shape corresponding to support structures SH described below, according to an example embodiment. Additionally, similarly to the channel structure CH, in the dummy vertical structures DCH, a string channel dielectric layer may be partially removed so that the string channel layer is connected to the common source layer 105. The dummy vertical structures DCH may include an insulating material, such as silicon oxide, silicon nitride, or silicon oxynitride.

The gate contact structures MC may be disposed in the second region R2, and may extend in the Z-direction by penetrating through at least a portion of the gate electrodes 130. Each of the gate contact structures MC may have an inclined side surface so that a width thereof increases toward the substrate 201, but may have a shape that does not correspond to the channel structures CH. For example, the gate contact structures MC may extend in the Z-direction only to the electrically connected gate electrode 130, and may not extend to an upper portion of the corresponding gate electrode 130. A length of the gate contact structures MC measured in the Z-direction may vary depending on the position of the electrically connected gate electrode 130. The gate contact structures MC may not have a bent portion formed in a portion corresponding to the first to third channel portions CH1, CH2 and CH3 of the channel structures CH on a side surface extending in the Z-direction. However, the shape of the gate contact structures MC is not limited thereto, and according to an example embodiment, the shape of the gate contact structures MC may correspond to the shape of the channel structures CH.

The gate contact structures MC may include gate contact plugs 701 and gate contact insulating layers 702 surrounding the gate contact plugs 701.

The gate contact plugs 701 may extend vertically from the lowermost interlayer insulating layer 120L to an upper portion of the gate structure GS through the gate structure GS, and may extend to the gate electrode 130 to which the gate contact plugs 701 are electrically connected. The gate contact plugs 701 may be coplanar with a lower surface of the channel structures CH and may be in contact with an upper surface of the first horizontal insulating layer 161. The gate contact plugs 701 may be connected to the gate electrode 130 on a lower surface of the gate electrode 130 to which the gate contact plugs 701 is electrically connected. In an example embodiment, the gate contact plugs 701 may be disposed in a form in which the lower surface of the gate electrode 130 is partially recessed. Each of the gate contact plugs 701 may include a metal, for example, tungsten (W), copper (Cu) and aluminum (Al).

The gate contact insulating layers 702 may be disposed on side surfaces of the gate contact plugs 701. The gate contact insulating layers 702 may surround the side surfaces of the gate contact plugs 701 and may insulate other gate electrodes 130 to which the gate contact plugs 701 is not electrically connected, from the gate contact plugs 701. In the gate contact insulating layers 702, a length thereof measured in the Z-direction may be shorter than a length of the gate contact plugs 701 measured in the Z-direction so as to expose upper ends of the gate contact plugs 701. The gate contact insulating layer 702 may include an insulating material, and may include at least one of SiO, SiN, SiON, SiCN, or SiOCN in an example embodiment.

The support structures SH may be disposed in the second region R2. Although not illustrated in FIG. 1, the support structures SH may be spaced apart from each other in the second region R2 while forming rows and columns on plan view. The support structures SH may have a pillar shape penetrating through at least some of the gate electrodes 130 and may include regions protruding from side surfaces thereof toward the gate electrodes 130. The support structures SH may have a diameter greater than maximum diameters of the channel structures CH and the dummy channel structures DCH and may have a diameter smaller than maximum diameters of the gate contact structures MC. The support structures SH may include an insulating material such as an oxide, a nitride, an oxynitride, or an oxycarbide, as an insulating structure, and may have a structure different from the dummy channel structures DCH. However, the present disclosure is not limited thereto, and the support structures SH may also have a shape corresponding to the channel structures CH, similarly to the dummy channel structure DCH. The support structures SH may be supporters that prevent deformation, such as a warpage of a plurality of gate electrodes 130 and interlayer insulating layers 120 stacked in the Z-direction.

The first cell region insulating layer 191 may be disposed between the second horizontal insulating layer 163 and the first and second gate electrodes 131 and 133. The first cell region insulating layer 191 may be disposed in a lower end of the second horizontal insulating layer 163 in the second region R2 and the third region R3 in which the vertical channel structures PCH1, PCH2, PCH3 and PCH4 are disposed. The first cell region insulating layer 191 may not be disposed in the first region R1 and may not overlap the channel structures CH. The first cell region insulating layer 191 may be interposed between the first and second gate electrodes 131 and 133 and the channel connection patterns 171 and 173 to insulate the first and second gate electrodes 131 and 133 and the channel connection patterns 171 and 173. The first cell region insulating layer 191 may include an insulating material, and may include, for example, at least one of silicon oxide, silicon nitride, or silicon carbide, and according to example embodiments, the first cell region insulating layer 191 may be formed of a plurality of insulating layers. When the first cell region insulating layer 191 includes the same material as the second horizontal insulating layer 163, interfaces between the first cell region insulating layer 191 and the second horizontal insulating layer 163 may not be distinguished.

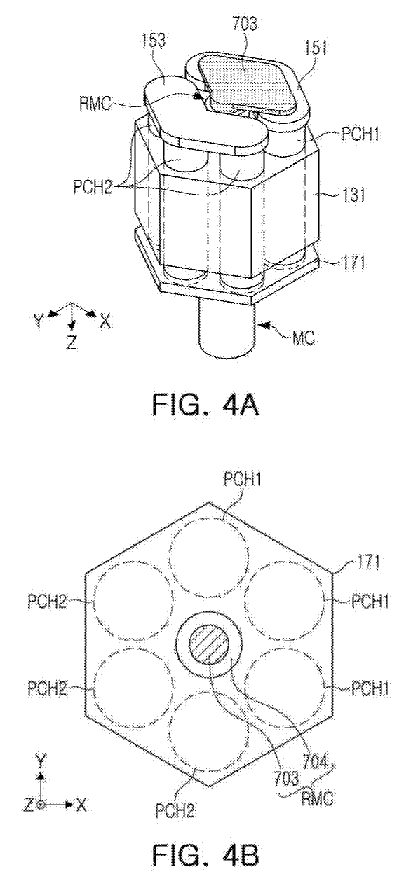

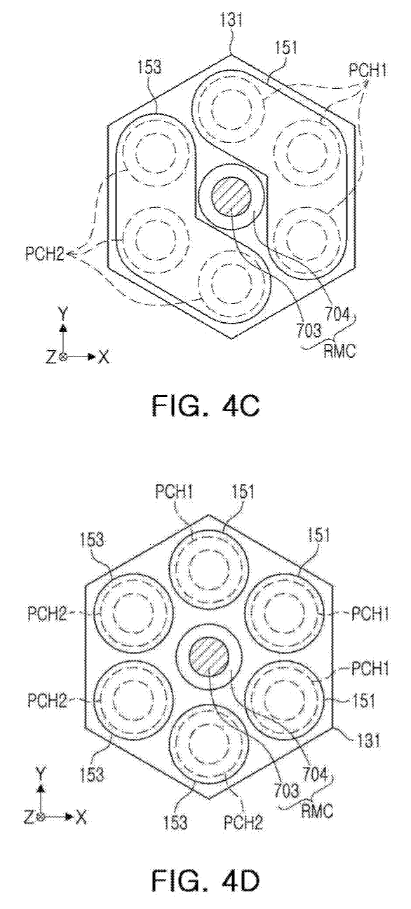

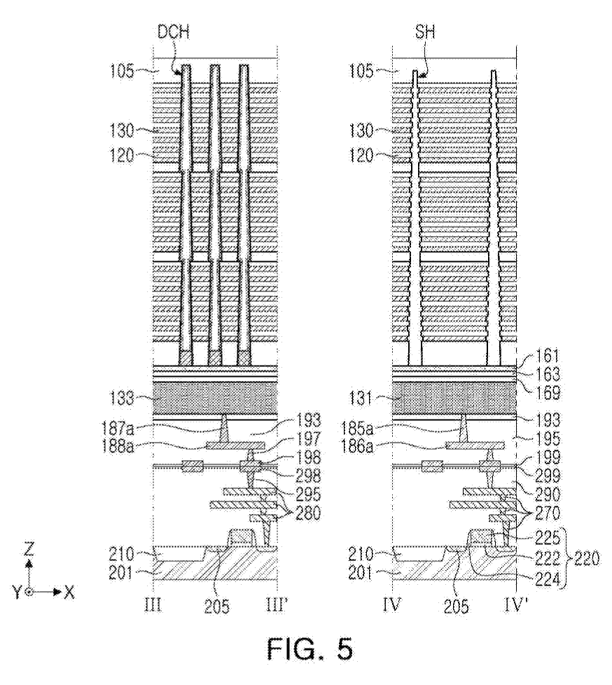

FIGS. 4A-4D are exploded perspective views and partial plan views illustrating some components of a semiconductor device according to example embodiments. FIG. 4A illustrates a perspective view of a relative structure of vertical channel structures disposed in the second semiconductor structure S2 of the semiconductor device 100. FIG. 4B illustrates a plane view of a channel connection pattern 171 when viewed from below in FIGS. 4A, and 4C illustrates a plane view of channel connection pads 151 and 153 and the first gate electrode 131 when viewed from above. FIG. 4D is a view illustrating various modified examples of the channel connection pads 151 and 153, and illustrates a cross-section corresponding to FIG. 4C.

FIGS. 3C and 3D and 4A-4D illustrate that a stacking direction of each layer is reversed vertically with the stacking direction in FIG. 2A. In the following description, the descriptions of ‘upper portion,’ ‘upper end,’ ‘on,’ ‘above,’ ‘lower portion,’ ‘lower end,’ ‘under,’ and ‘below’ may be explained based on the Z-direction illustrated in the drawing. For example, ‘upper portion,’ ‘upper end,’ ‘on,’ and ‘above’ may refer to a position in the Z-direction, while ‘lower portion,’ ‘lower end,’ ‘under,’ and ‘below’ may refer to a position in an opposite direction to the Z-direction. In other words, ‘upper portion,’ ‘upper end,’ ‘on,’ and ‘above’ may refer to an upper direction of the drawing in FIG. 2A, while they may refer to a lower direction of the drawings in FIGS. 3C, 3D, and 4A-4D, including FIG. 2B. Additionally, ‘lower portion,’ ‘lower end,’ ‘under,’ and ‘below’ may refer to a lower direction of the drawing in FIG. 2A, while they may refer to an upper direction of the drawings in FIGS. 3C, 3D, and 4A-4D, including FIG. 2B.

In addition to FIGS. 1, 2A, 2B, 3A, 3B, 3C and 3D, referring to FIGS. 4A-4D, the semiconductor device 100 may include vertical channel structures PCH1, PCH2, PCH3 and PCH4 disposed in the second region R2 and/or the third region R3, channel connection patterns 171 and 173 connecting different vertical channel structures PCH1, PCH2, PCH3 and PCH4, and an upper contact structure RMC connecting a gate contact structure MC and one of the vertical channel structures PCH1, PCH2, PCH3 and PCH4. The vertical channel structures PCH1, PCH2, PCH3 and PCH4 may form a channel of transistors transmitting an electric signal applied from the first semiconductor structure S1 to at least one of the gate electrodes 130 of the second semiconductor structure S2, for example, a pass transistor that applies a pass voltage, a program voltage, or the like, during an operation of the semiconductor device 100. The channel connection patterns 171 and 173 may connect different vertical channel structures PCH1, PCH2, PCH3 and PCH4 to form a channel of one transistor together therewith. The pass transistor may be connected to at least some of the first semiconductor structure S1 or the gate electrodes 130 to apply the voltage thereto.

The first vertical channel structures PCH1 and the second vertical channel structures PCH2 may be disposed in a first through-hole VPT1 penetrating through the first gate electrode 131 in the second region R2, and the upper contact structure RMC connected to the gate contact structure MC may be disposed in a second through-hole VPT2 penetrating through the first gate electrode 131. Each of the first and second vertical channel structures PCH1 and PCH2 may extend in the Z-direction by penetrating through the first gate electrode 131 in the second region R2. Each of the first and second vertical channel structures PCH1 and PCH2 may have an inclined side surface so that a width thereof increases toward the substrate 201.

The first through-holes VPT1 may be disposed to surround the second through-hole VPT2. One or more first vertical channel structures PCH1 and one or more second vertical channel structures PCH2 disposed in the first and second through-holes VPT1 and VPT2 may form a group and may surround an upper contact structure RMC. For example, the semiconductor device 100 may be disposed such that three first vertical channel structures PCH1 and three second vertical channel structures PCH2 form a group and surround an upper contact structure RMC. The three first vertical channel structures PCH1 and the three second vertical channel structures PCH2 may be disposed adjacently to each other. The six first and second vertical channel structures PCH1 and PCH2 are disposed in a hexagonal shape in plan view, and the upper contact structure RMC may be disposed in a center thereof. However, the arrangement of the first and second vertical channel structures PCH1 and PCH2 on plan view is not limited thereto. In FIG. 4A, three first vertical channel structures PCH1 and three second vertical channel structures PCH2 are illustrated as forming a group, but are not necessarily disposed in a hexagonal shape, and an arrangement shape of the first and second vertical channel structures PCH1 and PCH2 forming a group may be variously changed.

As illustrated in FIG. 3C, the first and second vertical channel structures PCH1 and PCH2 may include a vertical channel layer 142, a vertical channel dielectric layer 144, a vertical channel embedded insulating layer 146, and a vertical channel pad 148.

The vertical channel layer 142 may be formed in an annular shape surrounding the internal vertical channel embedded insulating layer 146. The vertical channel layer 142 may be formed to cover a side surface and an upper surface of the vertical channel buried insulating layer 146, and a portion of the vertical channel layer 142 covering the upper surface of the vertical channel buried insulating layer 146 may be connected to the first channel connection pattern 171. According to an example embodiment, the vertical channel layer 142 may be disposed in a form in which a lower surface of the first channel connection pattern 171 is partially recessed. The upper surface of the vertical channel buried insulating layer 146 covering an upper surface of the vertical channel layer 142 may be in contact with a recessed lower surface of the first channel connection pattern 171. However, the present disclosure is not limited thereto, and a shape of the vertical channel layer 142 may be variously changed. The first and second vertical channel structures PCH1 and PCH2 may include a vertical channel buried insulating layer 146 so that the vertical channel layer 142 may be formed not to be significantly thick, and the control of a channel region by the first gate electrode 131 may be facilitated and leakage current may be prevented from occurring.

The vertical channel dielectric layer 144 may be disposed between the first gate electrode 131 and the vertical channel layer 142. The vertical channel dielectric layer 144 may include a tunneling layer, a charge storage layer and a blocking layer sequentially stacked from the vertical channel layer 142. The vertical channel dielectric layer 144 may not recess a lower surface of the first channel connection pattern 171 and an upper end thereof may be in contact with the lower surface of the first channel connection pattern 171. However, a relative arrangement structure of the vertical channel layer 142, the vertical channel dielectric layer 144, and the first channel connection pattern 171 is not limited thereto and may be variously changed.

The vertical channel pad 148 may be disposed at least in one end in an extending direction of the first and second vertical channel structures PCH1 and PCH2. For example, the vertical channel pad 148 may be disposed in one end connected to the first channel connection pad 151, or a lower end thereof. The vertical channel pad 148 may be disposed below the vertical channel buried insulating layer 146, and a side surface thereof may be surrounded by the vertical channel layer 142. However, the present disclosure is not limited thereto, and the first and second vertical channel structures PCH1 and PCH2 may include a greater number of vertical channel pads 148. In the vertical channel pad 148, the vertical channel layer 142 and the vertical channel dielectric layer 144, surfaces thereof in contact with the first channel connection pad 151 may be coplanar with each other.

The first and second vertical channel structures PCH1 and PCH2 may include the vertical channel pad 148 at least in one end connected to the first and second channel connection pads 151 and 153. The first and second vertical channel structures PCH1 and PCH2 may transmit an electric signal applied from the first semiconductor structure S1 through the first and second channel connection pads 151 and 153. The first and second vertical channel structures PCH1 and PCH2 may include the vertical channel pad 148 in least at one end to prevent elements from being damaged even in the case that a high voltage electric signal is applied.

The descriptions of the channel layer 141, the channel dielectric layer 143, the channel buried insulating layer 145 and the channel pad 147 described above with reference to FIGS. 3A and 3B may be equally applied to the materials of the vertical channel layer 142, the vertical channel dielectric layer 144, the vertical channel buried insulating layer 146 and the vertical channel pad 148, respectively.

A diameter of the first and second vertical channel structures PCH1 and PCH2, or a maximum diameter in one end, may be greater than a diameter of the string channel structure SCH, or a maximum diameter in one end. The first and second vertical channel structures PCH1 and PCH2 and the string channel structures SCH may be disposed on substantially the same level in the second semiconductor structure S2, and may be distinguished according to the disposed region. Additionally, the first and second vertical channel structures PCH1 and PCH2 and the string channel structures SCH may be distinguished according to the diameter. According to an example embodiment, a maximum diameter of the first and second vertical channel structures PCH1 and PCH2 may be in a range of 1.5 to 4 times a maximum diameter of the string channel structures SCH, or may have a size of about 3 times or so. In this specification, a comparison of dimensions such as a width and a diameter may mean at least one of an average dimension, a dimension on the same level, or a maximum dimension, unless otherwise stated.

According to the maximum diameters of the first and second vertical channel structures PCH1 and PCH2, the number of the first and second vertical channel structures PCH1 and PCH2 disposed per unit area may be determined, and the number of the first and second vertical channel structures PCH1 and PCH2 forming a circuit element as a group may be determined. When the maximum diameters of the first and second vertical channel structures PCH1 and PCH2 are significantly large, the number of the first and second vertical channel structures PCH1 and PCH2 forming a circuit element may decrease, thereby reducing the element characteristics of the circuit element, such as current efficiency. On the other hand, when the maximum diameter of the first and second vertical channel structures PCH1 and PCH2 is significantly small, layers such as the vertical channel layer 142 and the vertical channel dielectric layer 144 may not be formed conformally. A maximum diameter of the first and second vertical channel structures PCH1 and PCH2 and the number of the first and second vertical channel structures PCH1 and PCH2 forming one circuit element may be determined by considering the element characteristics of the circuit element and conditions of the manufacturing process.

The first channel connection patterns 171 may be disposed adjacently to each other and spaced apart from each other in the second region R2. In FIG. 1, the first channel connection patterns 171 may be illustrated as being arranged in a hexagonal shape in plan view and having a form in which one surface of the other first channel connection patterns 171 adjacent to each other face the other. However, the present disclosure is not limited thereto, and the shape of the first channel connection patterns 171 in plan view may be variously changed.

The first channel connection patterns 171 may penetrate through the second horizontal insulating layer 163 in the second region R2, and may be disposed in an upper end of the first horizontal insulating layer 161 or upper ends of the first and second vertical channel structures PCH1 and PCH2. The first channel connection patterns 171 may be formed by removing a portion of the second horizontal insulating layer 163, and may have an upper surface which is coplanar with a lower surface of the first horizontal insulating layer 161. The first channel connection patterns 171 may be disposed in a lower end of the gate contact structures MC in the second region R2, and according to an example embodiment, the first channel connection patterns 171 may be disposed in a position corresponding to the gate contact structures MC. The second through-hole VPT2 penetrating through the first gate electrode 131 may extend in the Z-direction by penetrating through the first cell region insulating layer 191, the first channel connection pattern 171 and the first horizontal insulating layer 161. In the first channel connection patterns 171, a region corresponding to the gate contact structures MC may be penetrated by the second through-hole VPT2. An upper contact structure RMC may be disposed in the second through-hole VPT2 of the first channel connection patterns 171. The first channel connection patterns 171 may include a conductive material, and may include, for example, polycrystalline silicon or a metal.

A second cell region insulating layer 193 may be disposed below the first lower gate electrode 130L1 of the first region R1, the first gate electrode 131 of the second region R2, and the second gate electrode 133 of the third region R3. An upper surface of the second cell region insulating layer 193 may be coplanar with lower ends of the string channel structures SCH, and the first and second vertical channel structures PCH1 and PCH2. The second cell region insulating layer 193 may include at least one of an insulating material, for example, silicon oxide, silicon nitride, and silicon carbide, and according to example embodiments, the second cell region insulating layer 193 may be formed of a plurality of insulating layers.

The first channel connection pads 151 and the second channel connection pads 153 may be disposed below the second cell region insulating layer 193 in the second region R2. The first channel connection pad 151 may be disposed to correspond to the first vertical channel structures PCH1 and may be connected to the first vertical channel structures PCH1, and the second channel connection pad 153 may be disposed to correspond to the second vertical channel structures PCH2 and may be connected to the second vertical channel structures PCH2. Each of the first and second channel connection pads 151 and 153 connected to different vertical channel structures PCH1 and PCH2 may be spaced apart from each other. The first channel connection pads 151 may be electrically connected to the first vertical channel structures PCH1 and the upper contact structure RMC, and the second channel connection pads 153 may be electrically connected to the second vertical channel structures PCH2 and the second cell contact plug 185. The first channel connection pads 151 and the second channel connection pads 153 may include a conductive material, and may include, for example, polycrystalline silicon.

According to an example embodiment, one first channel connection pad 151 may be connected to several first vertical channel structures PCH1 belonging to one group, for example, three first vertical channel structures PCH1. One second channel connection pad 153 may be connected to several second vertical channel structures PCH2 belonging to one group, for example, three second vertical channel structures PCH2. As illustrated in FIG. 4C, each of the first channel connection pad 151 and the second channel connection pad 153 may have a partially bent ‘<’ shape and may be disposed to correspond to multiple first vertical channel structures PCH1 or second vertical channel structures PCH2.

However, the shapes of the first and second channel connection pads 151 and 153 are not limited thereto and may be variously changed. As illustrated in FIG. 4D, according to example embodiments, one first channel connection pad 151 may be connected to one first vertical channel structure PCH1, and one second channel connection pad 153 may be connected to one second vertical channel structure PCH2. In this case, plan view shapes of the first channel connection pad 151 and the second channel connection pad 153 may have a circular shape.

The upper contact structures RMC are disposed in the second region R2 and may extend in the Z-direction by penetrating through the second cell region insulating layer 193, the first gate electrode 131, the first cell region insulating layer 191, the first channel connection pattern 171 and the first horizontal insulating layer 161. Each of the upper contact structures RMC may have an inclined side surface so that a width thereof increases toward the substrate 201.

The upper contact structures RMC may include upper contact plugs 703 and upper contact insulating layers 702 surrounding the upper contact plugs 703.

The upper contact plugs 703 may be disposed in the second through-hole VPT2 and may extend vertically from the second cell region insulating layer 193 to the gate contact plugs 701. The upper contact plugs 703 may be disposed in a form in which a lower surface of the gate contact plugs 701 is partially recessed, and may be electrically connected to the gate contact plugs 701. Additionally, the upper contact plugs 703 may include an expanded portion 703e to cover the first channel connection pads 151. At least a portion of the upper contact plugs 703 may have a shape corresponding to the first channel connection pad 151, and may be electrically connected to the first channel connection pad 151. The upper contact plug 703 may be electrically connected to the gate electrodes 130 of the memory cell region and the first vertical channel structures PCH1 through the gate contact plug 701. The upper contact plug 703 may include a metal, for example, tungsten (W), copper (Cu), and aluminum (Al).

Upper contact insulating layers 704 may be disposed on side surfaces of the upper contact plugs 703. The upper contact insulating layers 704 may surround the side surfaces of the upper contact plugs 703, which may insulate the upper contact plugs 703 from the first gate electrode 131 and the first channel connection pattern 171 so as not to be directly connected to the first gate electrode 131 and the first channel connection pattern 171. At least a portion of the upper contact insulating layers 704 may be disposed between the upper contact plugs 703 and the first channel connection pattern 171. The upper contact insulating layers 704 may have a length measured in the Z-direction shorter than the length of the upper contact plugs 703 measured in the Z-direction so that a side surface of one end of the upper contact plugs 703 connected to the gate contact plug 701 is exposed. The upper contact insulating layer 704 may include an insulating material, and may include at least one of SiO, SiN, SiON, SiCN, or SiOCN in example embodiments.

The semiconductor device 100 may include third vertical channel structures PCH3 and fourth vertical channel structures PCH4 disposed in the third region R3, second channel connection patterns 173, and third channel connection pads 157 and fourth channel connection pads 159. The third vertical channel structures PCH3 and the fourth vertical channel structures PCH4 may extend in the Z-direction by penetrating through the second gate electrode 133, and one end of each may be connected to the second channel connection pattern 173. The other end of each of the third vertical channel structures PCH3 and the fourth vertical channel structures PCH4 may be connected to the third channel connection pad 157 and the fourth channel connection pad 159, respectively.

As illustrated in FIG. 3D, the structure and arrangement shape of each of the third vertical channel structures PCH3 and the fourth vertical channel structures PCH4, the second channel connection patterns 173, and the third channel connection pads 155 and the fourth channel connection pads 157 may correspond to the first vertical channel structures PCH1 and the second vertical channel structures PCH2, the first channel connection patterns 171, and the first channel connection pads 151 and the second channel connection pads 153. However, since the third and fourth vertical channel structures PCH3 and PCH4 disposed in the third region R3 are not connected to the gate electrodes 130 disposed on an upper portion of the first horizontal insulating layer 161, the upper contact structure RMC may not be disposed in the third region R3. The second channel connection pattern 173 may be connected to the third and fourth vertical channel structures PCH3 and PCH4 in a form not penetrated by a structure extending in the vertical direction.

The first channel connection patterns 171 may be disposed in a lower end of the gate contact structures MC in the second region R2, and the second channel connection patterns 173 may be disposed in a lower end of the dummy channel structures DCH in the third region R3. According to an example embodiment, the first channel connection patterns 171 may be disposed in a position corresponding to the gate contact structures MC, while the second channel connection patterns 173 may be disposed in a position unrelated to the arrangement of the dummy channel structures DCH. However, the present disclosure is not limited thereto, and the first channel connection patterns 171 may also be disposed in a position unrelated to the arrangement of the gate contact structures MC.

The third vertical channel structures PCH3 and the fourth vertical channel structures PCH4 may also be connected to each other through the second channel connection pattern 173 to form a channel region of a transistor constituting a circuit element. The third vertical channel structures PCH3 may be connected to the first lower gate electrode 130L1 of the first region R1 through the upper pad 159 connected to the third channel connection pad 155 and the third cell contact plug 187 and the third cell interconnection line 188. The fourth vertical channel structures PCH4 may be connected to the circuit element of the first semiconductor structure S1 through the fourth channel connection pad 157, the third cell contact plug 187 and the third cell interconnection line 188.

A third cell region insulating layer 195 may be disposed in a lower portion of the second cell region insulating layer 193. The third cell region insulating layers 195 may include an insulating material, and may include, for example, at least one of silicon oxide, silicon nitride, or silicon carbide, and according to example embodiments, at least one of the third cell region insulating layers 195 may be formed of a plurality of insulating layers. When the third cell region insulating layer 195 includes the same material as the second cell region insulating layer 193, an interface between the second and third cell region insulating layers 193 and 195 may not be distinguished.

The first cell contact plugs 181 and the first cell interconnection lines 182 may form second interconnection structures electrically connected to the memory cells in the second semiconductor structure S2. The first cell contact plugs 181 may be connected to the lower ends of the string channel structures SCH in the first region R1, and may be electrically connected to the channel structures CH and the gate electrodes 130. The first cell interconnection lines 182 may be connected to lower ends of the first cell contact plugs 181. Among the first cell interconnection lines 182, the first cell interconnection lines 182 disposed below the string channel structures SCH and/or the channel structures CH in the first region R1 may correspond to bit lines. Some of the first cell contact plugs 181 may be electrically connected to the first lower gate electrode 130L1 and may be connected to the third cell interconnection lines 188 in the third region R3.

The second cell contact plugs 185 and the second cell interconnection lines 186 may be disposed in the second region R2 and may form second interconnection structures electrically connected to the gate electrodes 130 in the second semiconductor structure S2. The second cell contact plugs 185 may be connected to one of the second channel connection pads 153 disposed in the second region R2, and the second cell interconnection lines 186 may be connected to lower ends of the second cell contact plugs 185. The second cell contact plugs 185 and the second cell interconnection lines 186 may be electrically connected to the circuit elements of the first semiconductor structure S1 and the first and second vertical channel structures PCH1 and PCH2.

The third cell contact plugs 187 and the third cell interconnection lines 188 may be disposed in the third region R3 and may form second interconnection structures electrically connected to the first lower gate electrode 130L1. The third cell contact plugs 187 may be disposed in a lower end of one of the third channel connection pads 155 and the fourth channel connection pads 157 disposed in the third region R3, and the third cell interconnection lines 188 may be connected to a lower end of the third cell contact plugs 187.

However, in example embodiments, the number of plugs and interconnection lines of the second interconnection structure may be variously changed. Each of the first to third cell contact plugs 181, 185 and 187 and the first to third cell interconnection lines 182, 186 and 188 may include a metal, and may include, for example, tungsten (W), copper (Cu), and aluminum (Al).

The second bonding vias 197 and the second bonding pads 198 may form second bonding structures bonding the second semiconductor structure S2 and the first semiconductor structure S1. The second bonding vias 197 and the second bonding pads 198 may be disposed below the first cell interconnection lines 182. The second bonding vias 197 may connect the first cell interconnection lines 182 and the second bonding pads 198, and the second bonding pads 198 may be bonded to the first bonding pads 298 of the first semiconductor structure S1. The second bonding insulating layer 199 may be bonded and connected to the first bonding insulating layer 299 of the first semiconductor structure S1. The second bonding vias 197 and the second bonding pads 198 may include a conductive material, and may include, for example, copper (Cu). The second bonding insulating layer 199 may include an insulating material, for example, at least one of SiO, SiN, SiCN, SiOC, SiON, or SiOCN.

The first and second semiconductor structures S1 and S2 may be bonded to each other by bonding of the first bonding pads 298 and the second bonding pads 198 and bonding of the first bonding insulating layer 299 and the second bonding insulating layer 199. The bonding of the first bonding pads 298 and the second bonding pads 198 may be, for example, copper (Cu)-to-copper (Cu) bonding, and the bonding of the first bonding insulating layer 299 and the second bonding insulating layer 199 may be, for example, dielectric-to-dielectric bonding, such as SiCN-to-SiCN bonding. The first and second semiconductor structures S1 and S2 may be bonded by hybrid bonding including copper (Cu)-to-copper (Cu) bonding and dielectric-to-dielectric bonding.

In the semiconductor device 100, each of the first and second vertical channel structures PCH1 and PCH2 forming a group may have one end connected to the same first channel connection pattern 171, and the other end connected to different channel connection pads 151 and 153. The vertical channel layer 142 of each of the first and second vertical channel structures PCH1 and PCH2 may have one end connected to the first channel connection pattern 171, and the other end connected to different channel connection pads 151 and 153, respectively. Additionally, the vertical channel pad 148 of each of the first and second vertical channel structures PCH1 and PCH2 may be connected to the first channel connection pad 151 and the second channel connection pad 153, respectively.

A transistor formed by the first and second vertical channel structures PCH1 and PCH2 may be electrically connected to the circuit elements of the first semiconductor structure S1 through the second channel connection pad 153, and may be electrically connected to the gate electrodes 130 of the memory cell region through the first channel connection pad 151, the upper contact structure RMC and the gate contact structure MC. A semiconductor device 100 may transmit an electric signal applied from the first semiconductor structure S1 to the gate electrodes 130 through the transistor formed by first vertical channel structures PCH1 and second vertical channel structures PCH2.

The first vertical channel structures PCH1 and the second vertical channel structures PCH2 may be mutually connected to the first channel connection pattern 171 to form a channel of a pass transistor that applies a voltage when the semiconductor device 100 operates. The voltage applied by the pass transistor may pass through the first and second vertical channel structures PCH1 and PCH2 and the first channel connection pattern 171. The vertical channel layer 142 of each of the first vertical channel structures PCH1 and the second vertical channel structures PCH2 may form a channel region of the pass transistor, and the first and second channel connection pads 151 and 153 may form a source/drain region of the pass transistor. The first channel connection pattern 171 may form a channel region of the first and second vertical channel structures PCH1 and PCH2 and the pass transistor, or may serve to connect the channel region formed by each of the first and second vertical channel structures PCH1 and PCH2. The semiconductor device 100 may have a smaller chip size since the pass transistor, which applies voltage during operations, is disposed in the second semiconductor structure S2 instead of the first semiconductor structure S1.

Since the semiconductor device 100 has different first and second vertical channel structures PCH1 and PCH2 connected to each other to form the channel of the transistor, as compared to a transistor formed of a single vertical channel structure, a length of the vertical channel structures PCH1 and PCH2 of the channel may be shortened, and a thickness of the gate electrode 131 may be thinner.

The first and second channel connection pads 151 and 153 connected to the first and second vertical channel structures PCH1 and PCH2 may be disposed on the same level in a horizontal direction, and may be in contact with the upper contact plug 703 or the second cell contact plugs 185 including metal, respectively. In the manufacturing process of the semiconductor device 100, after a forming process of the first and second channel connection pads 151 and 153, a forming process of the contact plugs including the metal may be performed, and a process of forming metal on the first and second channel connection pads 151 and 153 including polycrystalline silicon may be performed. A silicon-metal compound having low resistance may be formed at an interface between the first and second channel connection pads 151 and 153 and the contact plug. The semiconductor device 100 has a structure in which a channel of a transistor to which the electric signal is applied from the first semiconductor structure S1 extends in the Z-direction, but channel pads to which the electric signal is directly applied may be formed in an upper end during the manufacturing process, and there is an advantage in that a low-resistance compound may be formed in the channel pad portion. The transistor that applies the electric signal to the gate electrodes 130 of the memory cell region of the semiconductor device 100 may have voltage applied in both directions. The semiconductor device 100 may have a structure suitable for the transistor that applies the electric signal to the gate electrodes 130, in which the first and second channel connection pads 151 and 153 may function as source/drain regions disposed in both ends of the channel of the transistor.

Additionally, in both ends of the first and second vertical channel structures PCH1 and PCH2, the vertical channel layer 142 and the vertical channel pads 148 may form junctions with the first channel connection pattern 171 and the first and second vertical channel pads 151 and 153, respectively. Accordingly, even if a length of the first and second vertical channel structures PCH1 and PCH2 in the Z-direction becomes shorter, there is an advantage in that the breakdown voltage of the circuit elements formed by the first and second vertical channel structures PCH1 and PCH2 is high.

FIG. 5 is a partially-enlarged view illustrating a semiconductor device according to example embodiments. FIG. 5 illustrates a cross-section taken along lines III-III’ and IV-IV’ of FIG. 1.

Referring to FIG. 5, the semiconductor device 100 may include a first contact plug 185a connected to the first gate electrode 131 in the second region R2, a first interconnection line 186a connected to the first contact plug 185a, a second contact plug 187a connected to the second gate electrode 133 in the third region R3, and a second interconnection line 188a connected to the second contact plug 187a. Each of the first contact plug 185a and the second contact plug 187a may be either the second cell contact plug 185 or the third cell contact plug 187, and each of the first interconnection line 186a and the second interconnection line 188a may be either the second cell interconnection line 186 or the third cell interconnection line 188.

The first gate electrode 131 may receive a gate signal from a circuit element of the first semiconductor structure S1 through the first contact plug 185a and the first interconnection line 186a, and the second gate electrode 133 may receive a gate signal from a circuit element of the first semiconductor structure S1 through the second contact plug 187a and the second interconnection line 188a. The first gate electrode 131 and the second gate electrode 133 may function as gate electrodes of a transistor composed of vertical channel structures.

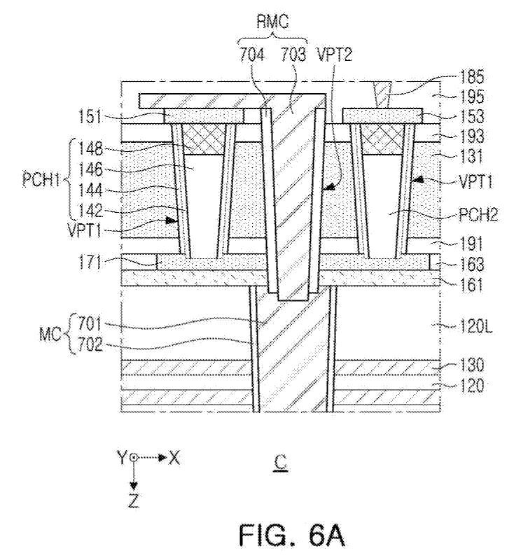

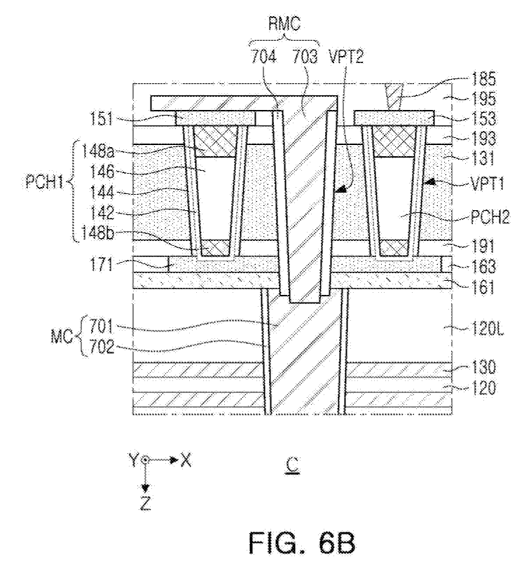

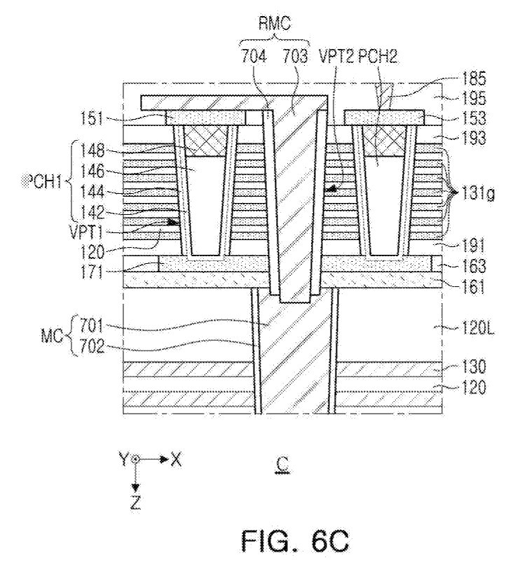

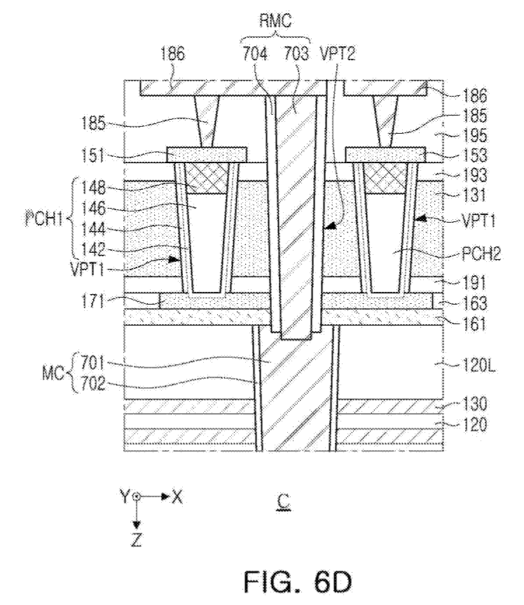

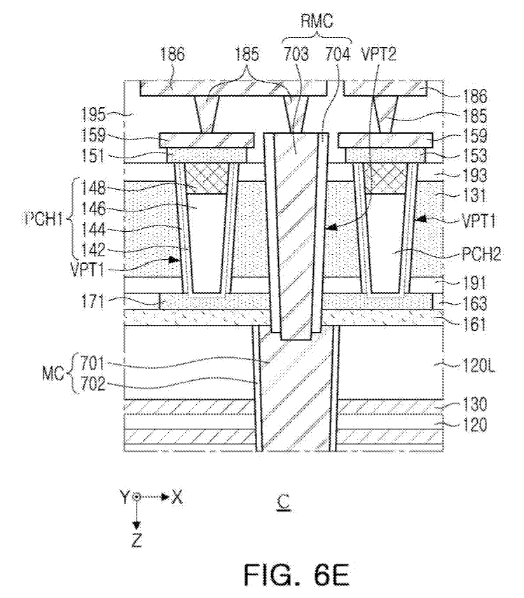

FIGS. 6A-6E are partially-enlarged views illustrating semiconductor devices according to example embodiments. FIGS. 6A-6E illustrate a region corresponding to FIG. 3C.

Referring to FIGS. 6A and 6B, in the semiconductor device 100, the shapes of the first and second vertical channel structures PCH1 and PCH2 may be different from the example embodiment of FIG. 3C.

As illustrated in FIG. 6A, the vertical channel layer 142 of the first and second vertical channel structures PCH1 and PCH2 may be formed so as to cover only a side surface the vertical channel buried insulating layer 146 without covering a lower surface thereof. The vertical channel layer 142 may have a smaller area in contact with the first channel connection pattern 171 than the example embodiment of FIG. 3C, and a lower surface of the vertical channel buried insulating layer 146 may be in contact with the first channel connection pattern 171.

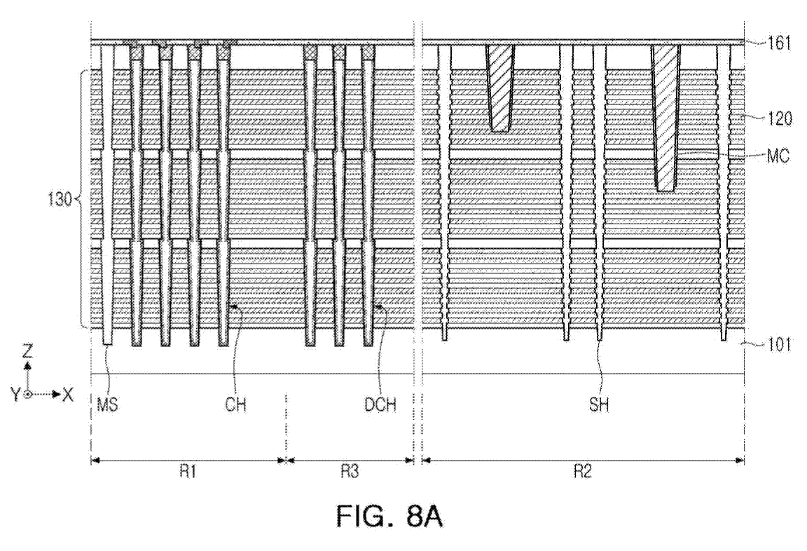

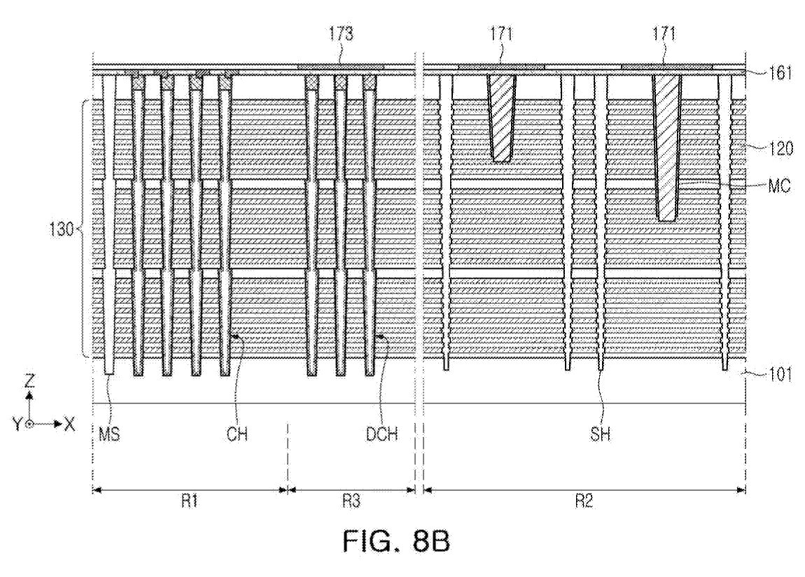

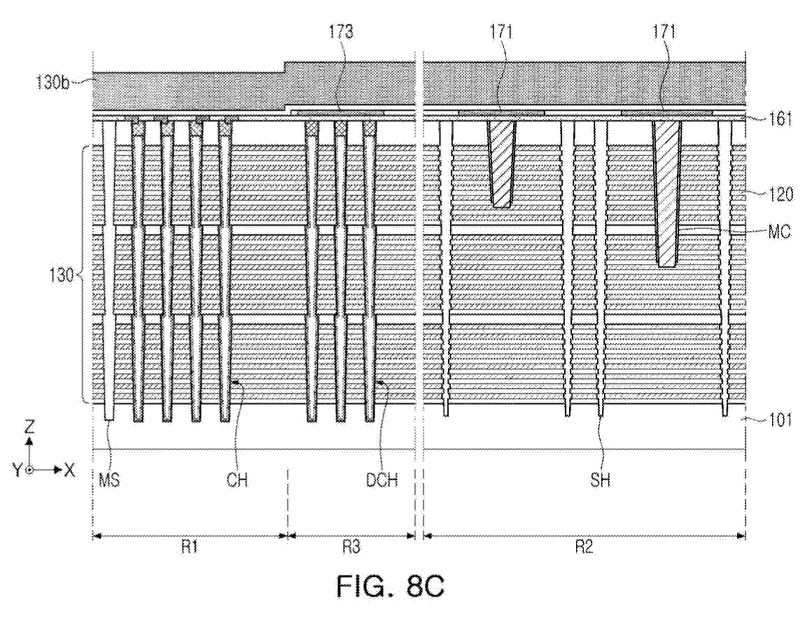

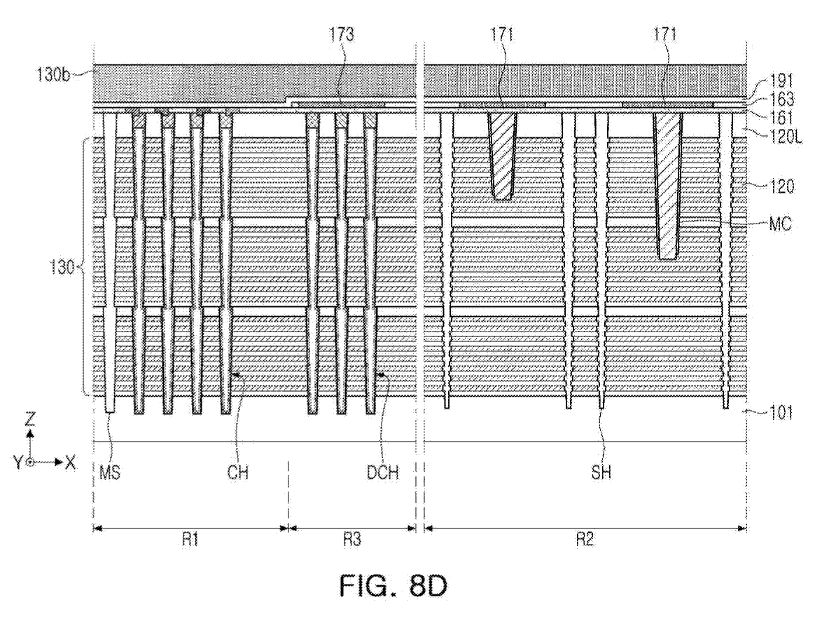

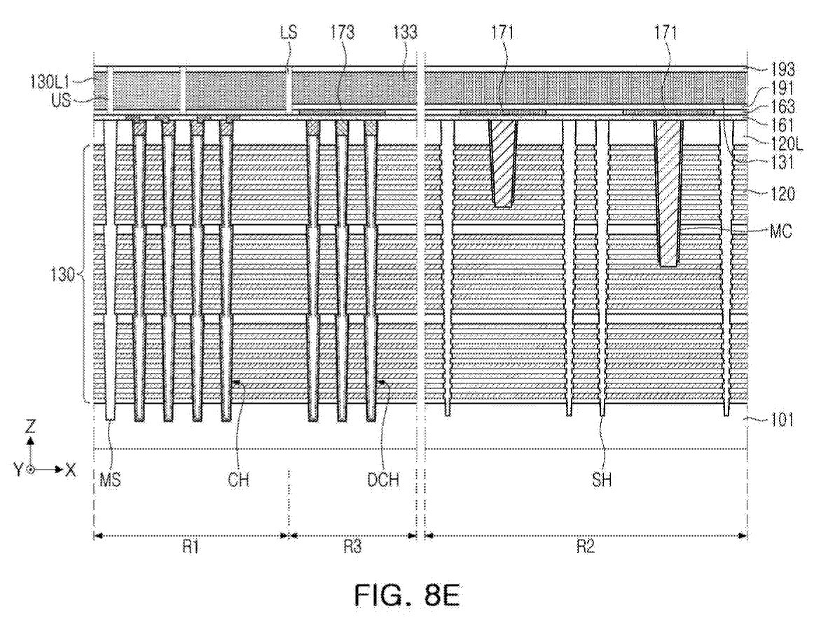

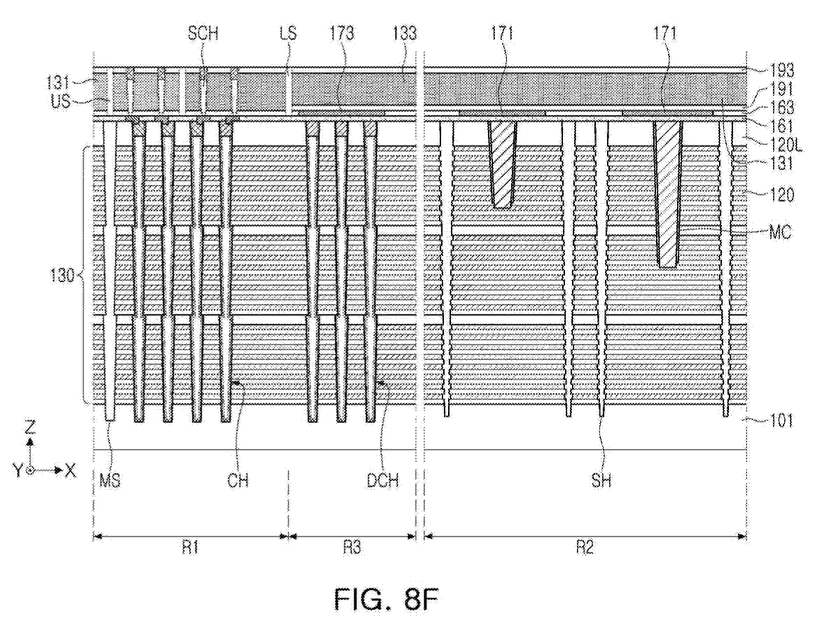

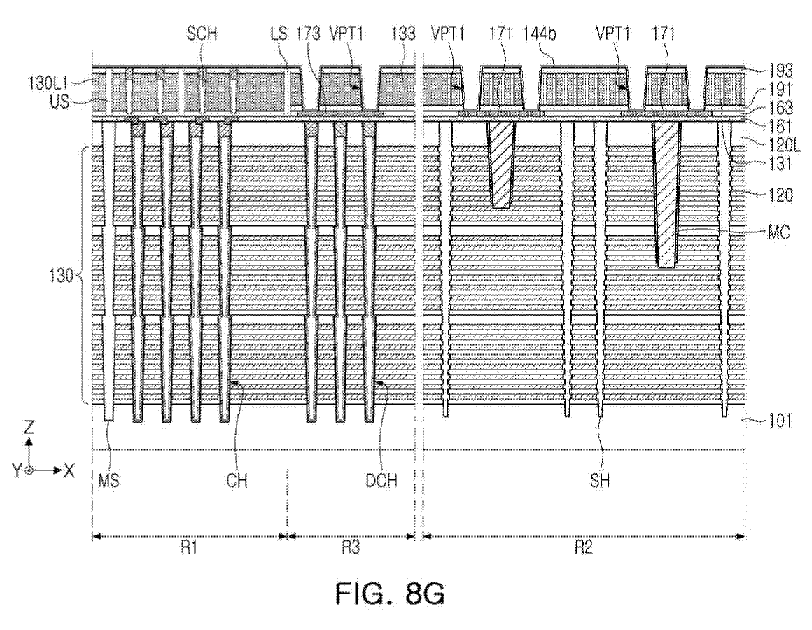

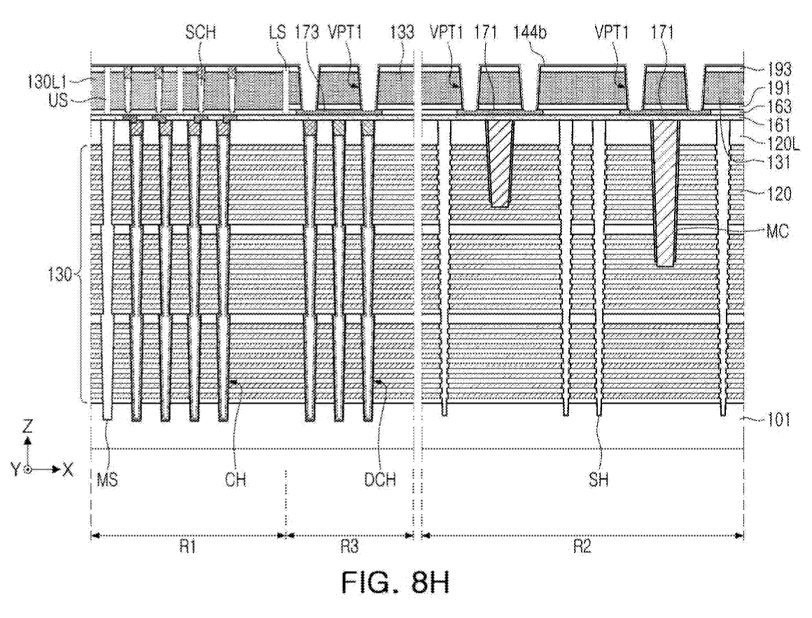

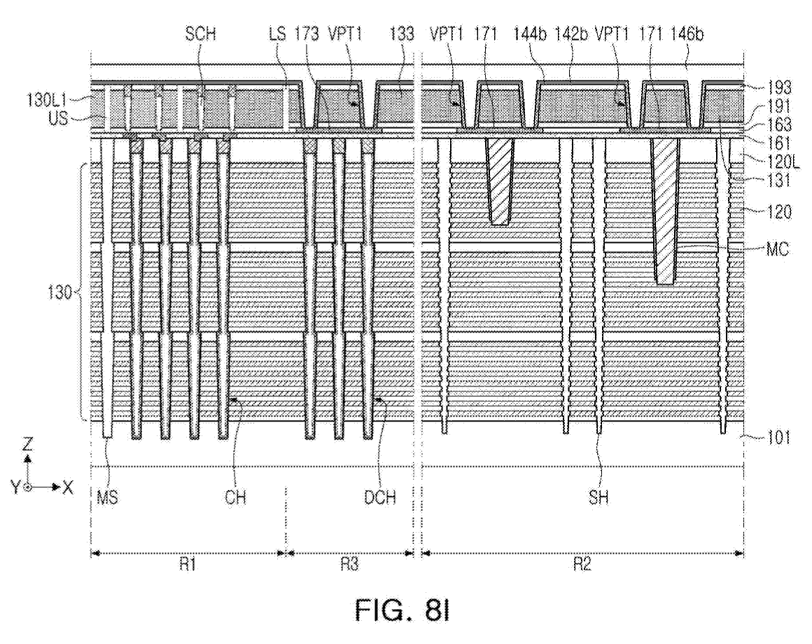

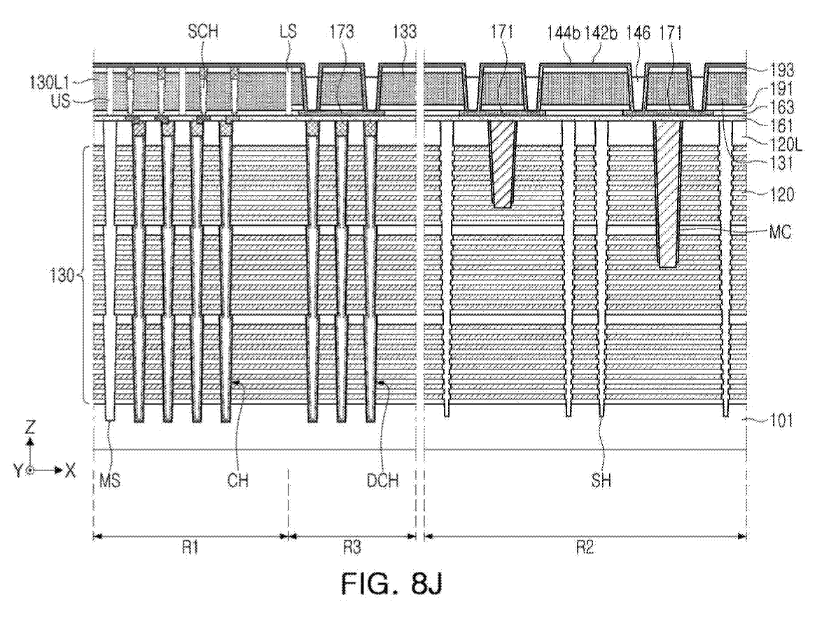

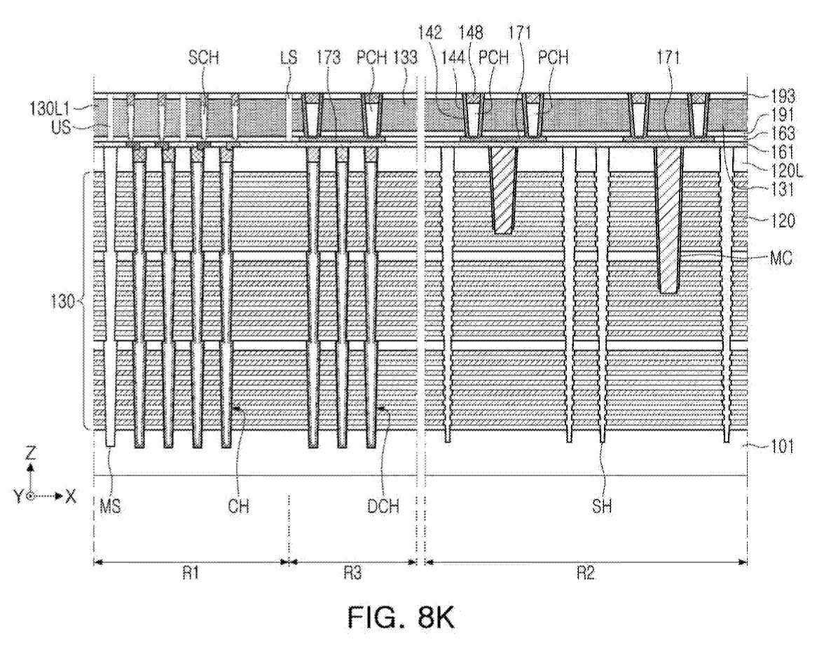

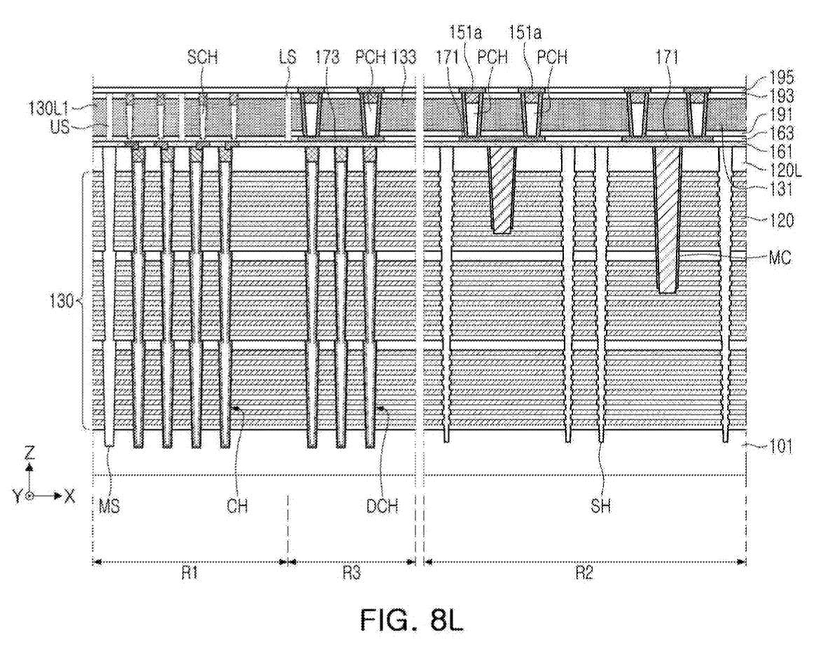

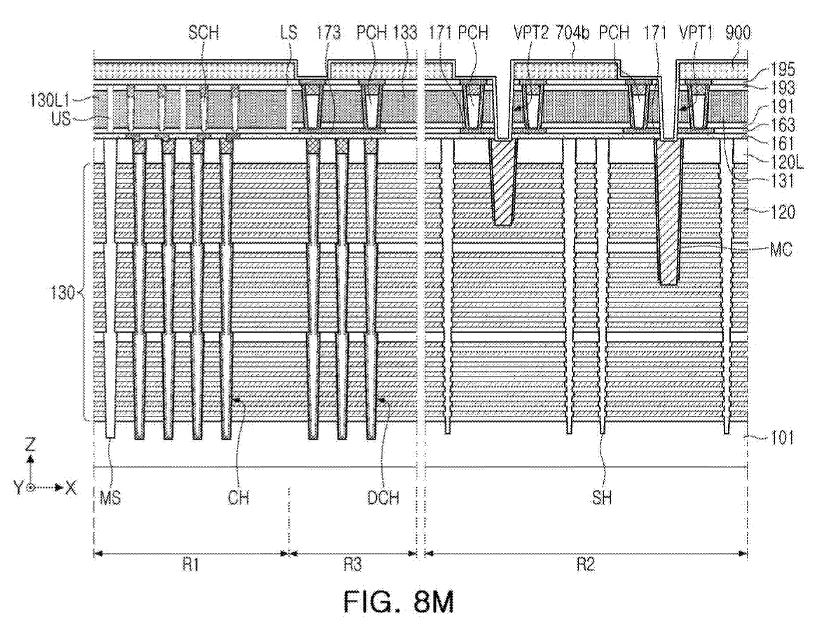

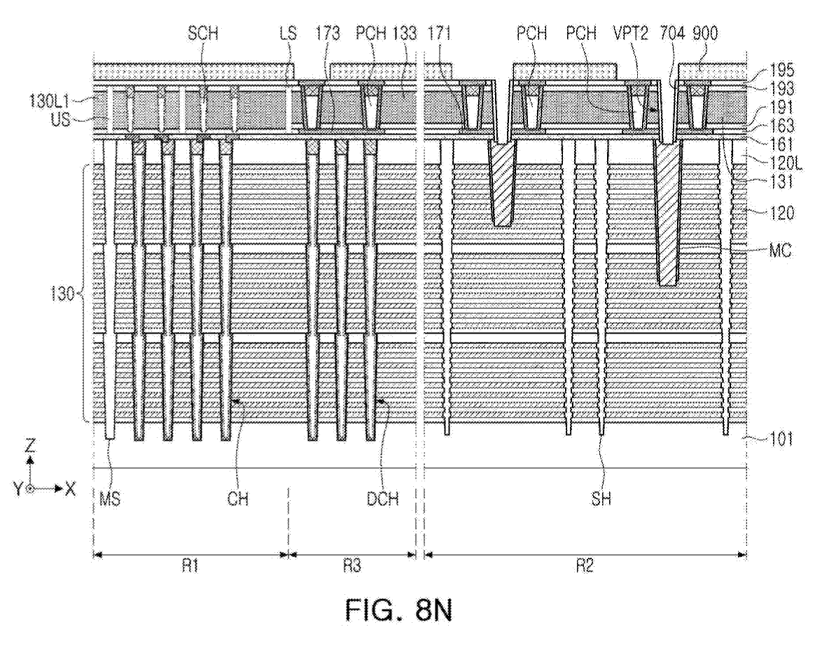

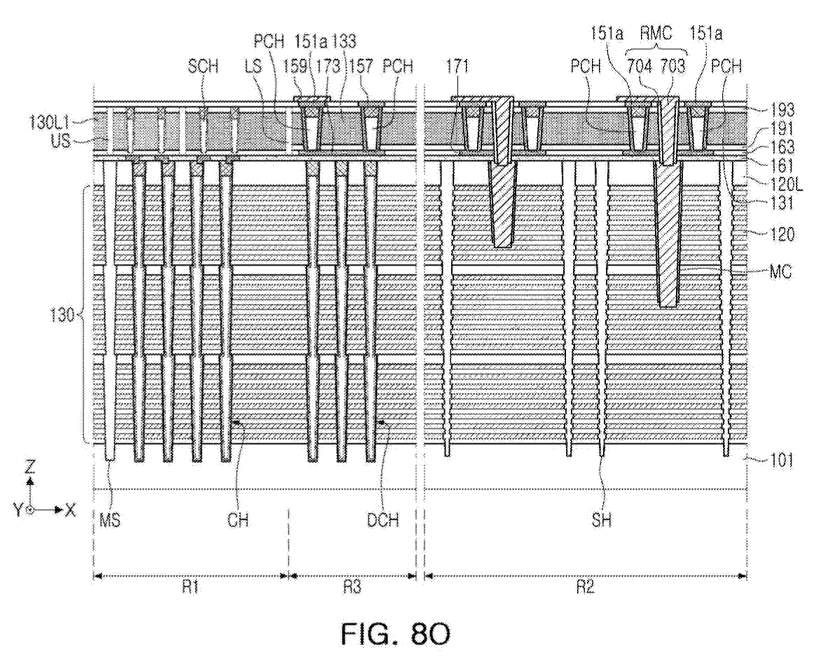

An example embodiment of FIG. 6A may have a different manufacturing process from example embodiments of FIGS. 2A-3D. The example embodiment of FIGS. 2A-3D may be a structure manufactured by, in a forming process of the vertical channel layer 142 described with reference to FIG. 8I below, forming a channel layer covering an inner sidewall of the first through-hole VPT1 and an upper surface of the first channel connection pattern 171, and then performing a deposition process of forming a vertical channel buried insulating layer 146 without an additional etching process. On the other hand, an example embodiment of FIG. 6A may be a structure manufactured by, in a forming process of the vertical channel layer 142, forming a channel layer, then performing an additional etching process of exposing an upper surface of the first channel connection pattern 171 inside the first through-hole VPT1, and then performing a deposition process of forming a vertical channel buried insulating layer 146. In the semiconductor device 100, since the first channel connection pattern 171 connected to the vertical channel layer 142 of the first and second vertical channel structures PCH1 and PCH2 includes polycrystalline silicon, the resistance at a bonding interface with the vertical channel layer 142 may be low, so that a contact area between the vertical channel layer 142 and the first channel connection pattern 171 may be relatively small.

As illustrated in FIG. 6B, the first and second vertical channel structures PCH1 and PCH2 may include a first vertical channel pad 148a and a second vertical channel pad 148b in both ends in a vertical direction. The first vertical channel pad 148a may be connected to the first channel connection pad 151 or the second channel connection pad 153, and the second vertical channel pad 148b may be connected to the first channel connection pattern 171. The example embodiment of FIG. 6B, unlike the example embodiments of FIGS. 2A-3D, may be a structure manufactured by forming the second vertical channel pad 148b in the first through-hole VPT1 before forming the vertical channel buried insulating layer 146, and then performing a deposition process for forming the vertical channel buried insulating layer 146. The vertical channel structures PCH1 and PCH2 of FIG. 6B include vertical channel pads 148a and 148b in the both ends, so that even in the case that a high-voltage electric signal is applied, the vertical channel layer 142 forming the channel region may be prevented from being damaged.

Referring to FIG. 6C, in the semiconductor device 100, a shape of the first gate electrode 131 may be different from that of the example embodiment of FIG. 3C. In the semiconductor device 100, the first gate electrode 131 may include metal and may be comprised of a plurality of metal gate electrodes 131g stacked and spaced apart from each other in the Z-direction. Although not illustrated in the drawing, the second gate electrode 133 and the first lower gate electrode 130L1 may also be comprised of a plurality of metal gate electrodes 131g. Unlike the embodiment of FIG. 3c, the first gate electrode 131 may be comprised of the plurality of metal gate electrodes 131g. The plurality of gate electrodes 131g may be alternately stacked with interlayer insulating layers 120 disposed therebetween. The metal gate electrodes 131g may be electrically connected to the circuit elements of the first semiconductor structure S1. The metal gate electrodes 131g may be connected to different circuit elements, but the present disclosure is not limited thereto, and at least some of the metal gate electrodes 131g may be connected to the same circuit element and an electric signal may be applied thereto.

Referring to FIGS. 6D and 6E, in the semiconductor device 100, the shape of the second interconnection structure connected to the first and second channel connection pads 151 and 153 may be different from that in the example embodiment of FIG. 3C.

As illustrated in FIG. 6D, each of the first channel connection pad 151 and the second channel connection pad 153 may be connected to the second cell contact plug 185, and the upper contact plug 703 of the upper contact structure RMC may be connected to the second cell connection line 186 and electrically connected to the first channel connection pad 151. The upper contact plug 703 and the upper contact insulating layer 704 may have a shape extending from a lower surface of the second cell connection line 186 to the gate contact structure MC. However, the present disclosure is not limited thereto, and the upper contact structure RMC may also extend from the second cell region insulating layer 193 to the gate contact structure MC, and may be connected to the second cell contact plug 185. In an example embodiment of FIG. 6D, the upper pads 159 may be omitted, and the first channel connection pad 151 and the upper contact structure RMC may be electrically connected through the second cell interconnection line 186.

As illustrated in FIG. 6E, each of the first channel connection pad 151 and the second channel connection pad 153 may be connected to the upper pad 159, and the upper pad 159, and the upper contact plug 703 of the upper contact structure RMC may be connected to the second cell interconnection line 186 through the second cell contact plug 185. In an example embodiment of FIG. 6E, each of the first and second channel connection pads 151 and 153 may be connected to the upper pad 159, and the upper pad 159 and the upper contact structure RMC may be electrically connected to the second cell interconnection line 186 through the second cell contact plug 185, respectively.

The example embodiments of FIGS. 6D and 6E may have different manufacturing processes from the example embodiments of FIGS. 2A-3D. In the example embodiment of FIGS. 2A-3D, in a forming process of the upper contact plug 703 described with reference to FIG. 8O below, a metal coating process of filling the inside of the second through-hole VPT2 in a state in which an upper end of the first channel connection pad 151 is open may be performed, so that an upper contact plug 703 may be formed so that a portion thereof extends to an upper portion of the first channel connection pad 151. On the other hand, in the example embodiment of FIGS. 6D and 6E, a forming process of the upper contact plug 703 may be performed in a state in which each of the first and second channel connection pads 151 and 153 are covered with an insulating layer, and in a separate subsequent process, the second cell contact plug 185 and the second cell interconnection line 186 may be formed so that the first channel connection pad 151 and the upper contact plug 703 may be electrically connected to each other.

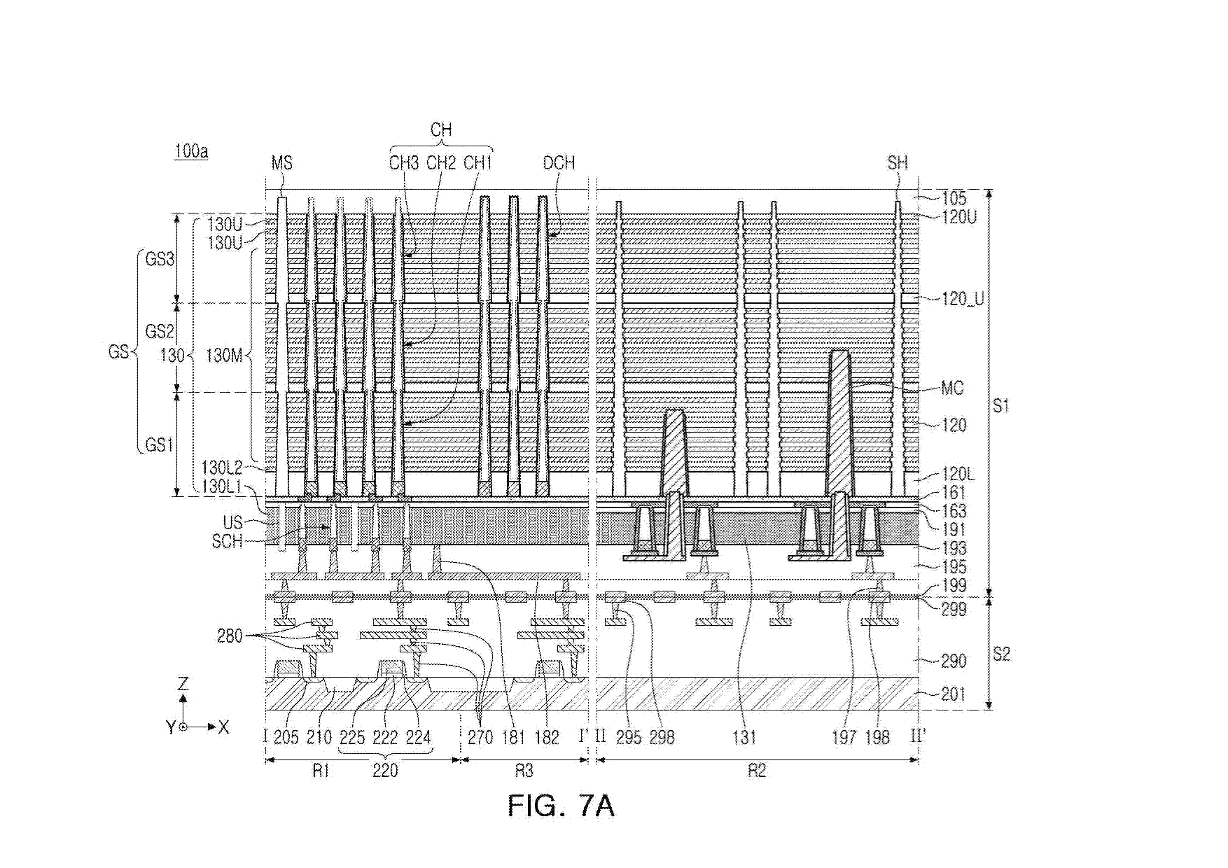

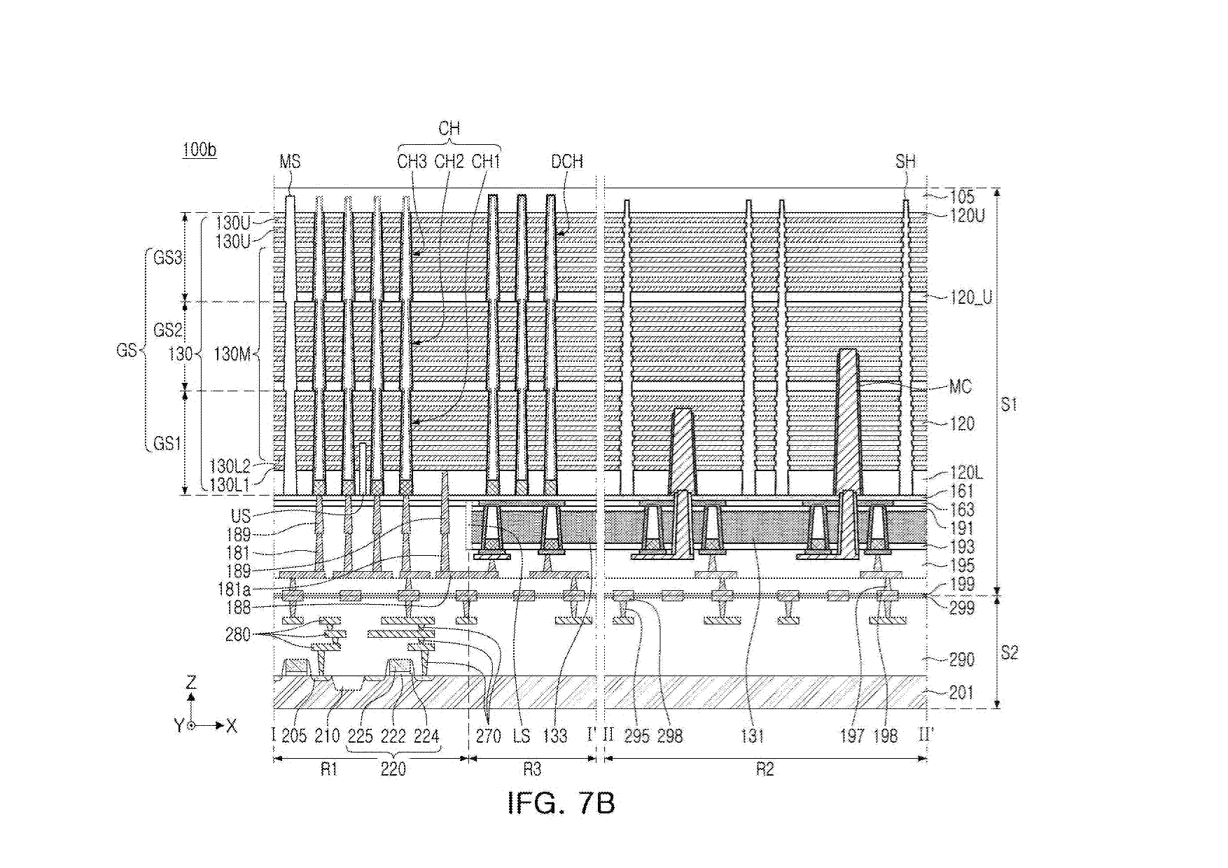

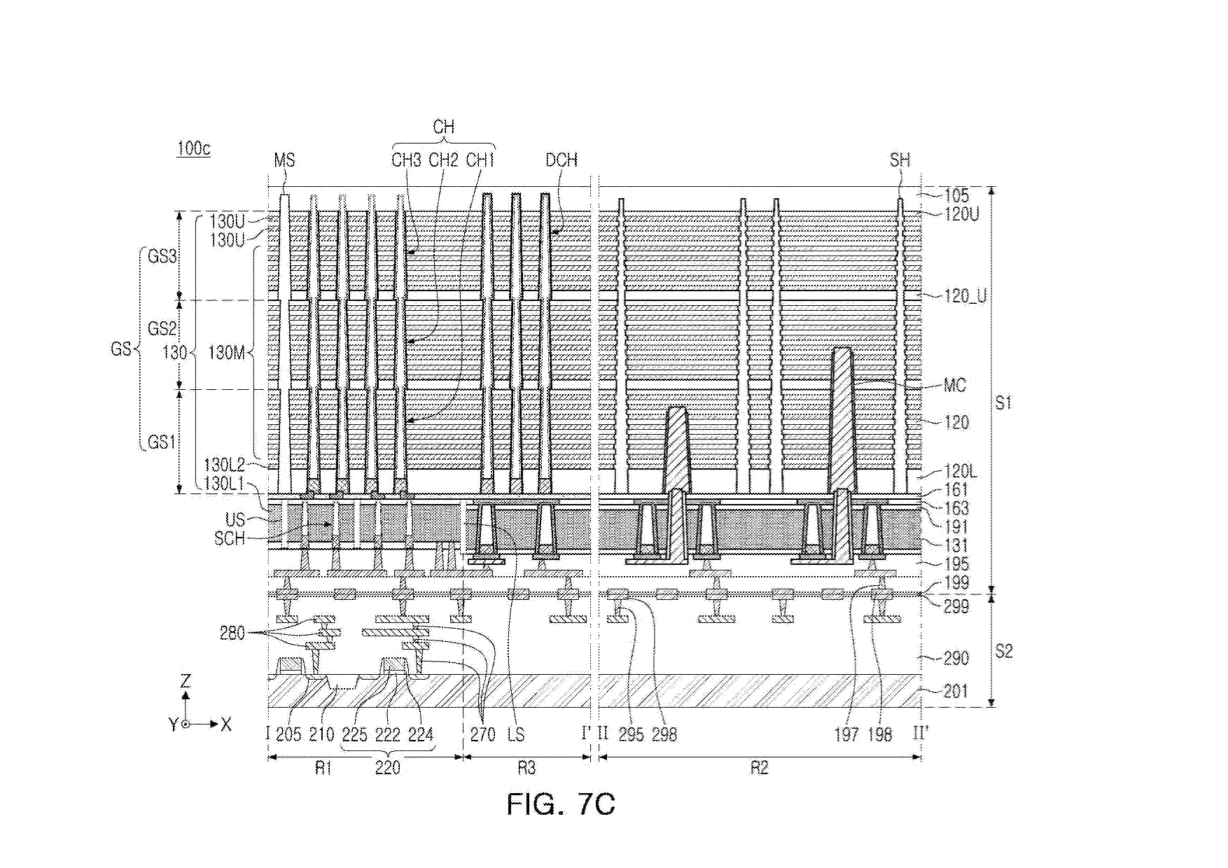

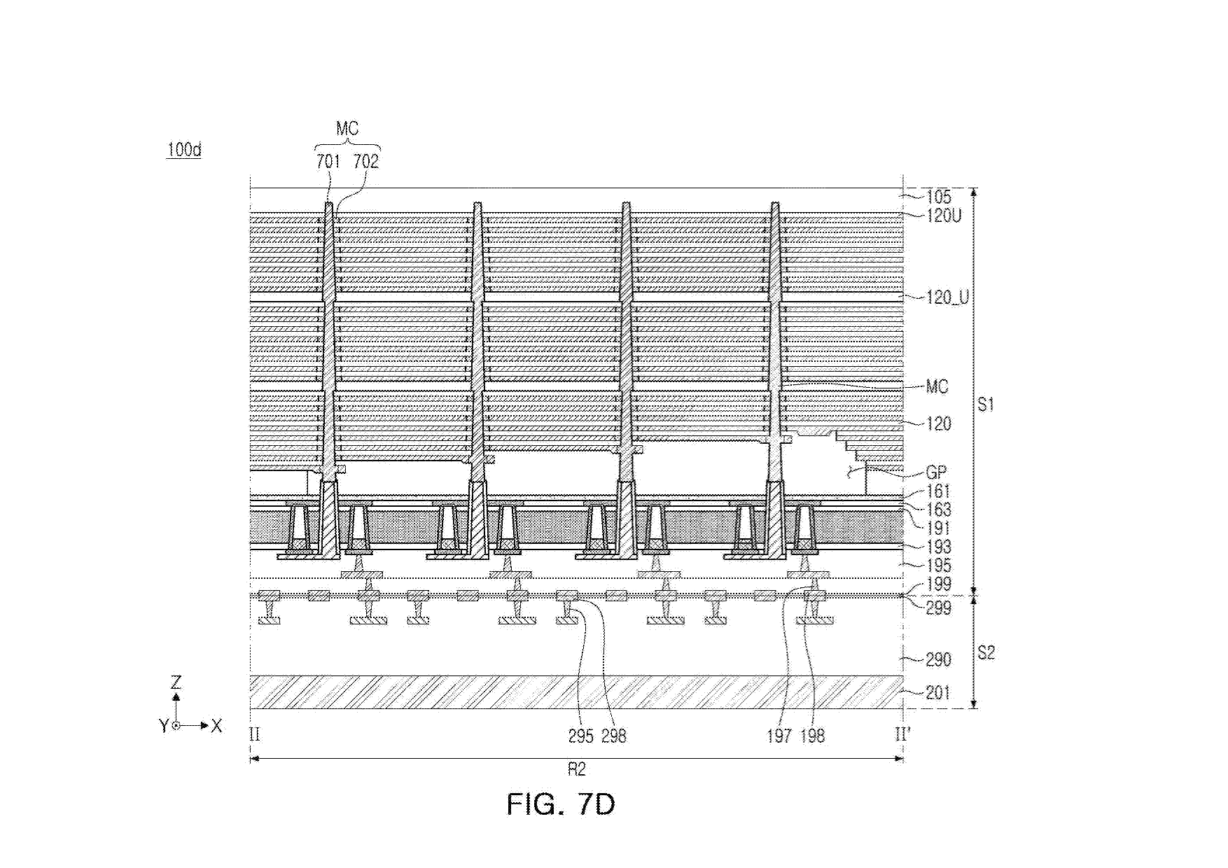

FIGS. 7A-7D are cross-sectional views of semiconductor devices according to example embodiments. FIGS. 7A-7C illustrate a region corresponding to FIGS. 2A, and 7D illustrates a partial cross-section of the second region R2 of the semiconductor device 100.

Referring to FIG. 7A, in a semiconductor device 100a, the third vertical channel structures PCH3 and the fourth vertical channel structures PCH4 may be omitted. Additionally, the second channel connection pattern 173, the third and fourth channel connection pads 155 and 157 may also be omitted. The third separation region LS between the first region R1 and the third region R3 may also be omitted, so that the first lower gate electrode 130L1 may extend to the third region R3 and may be electrically connected to the first semiconductor structure S1 through the third cell contact plug 187 and the third cell interconnection line 188 in the third region R3. In the semiconductor device 100a, as the third vertical channel structures PCH3 are omitted, a circuit element for applying a gate signal to the first lower gate electrode 130L1 may be further disposed in the first semiconductor structure S1. The first lower gate electrode 130L1 may be connected to the first cell interconnection line 182 through the first cell contact plug 181.

Referring to FIG. 7B, in a semiconductor device 100b, string channel structure SCH may be omitted, and the first lower gate electrode 130L1 may be moved to an upper end of the first horizontal insulating layer 161. The second separation regions US may be formed to penetrate through the lowermost interlayer insulating layer 120L and a portion of the gate electrodes 130 adjacent to the first horizontal insulating layer 161, and the third separation regions LS may be formed to separate the first gate electrode 131 and the second gate electrode 133 between the second region R2 and the third region R3.

Each of the first horizontal insulating layer 161 and the second horizontal insulating layer 163 may be disposed in a lower end of the lowermost interlayer insulating layer 120L. As the string channel structure SCH is omitted, the first horizontal insulating layer 161 and the second horizontal insulating layer 163 do not function as etch stop layers, and may be used when forming the first and second channel connection patterns 171 and 173. The first horizontal insulating layer 161 and the second horizontal insulating layer 163 may include an insulating material, but the type of the insulating material may be less limited than in the example embodiment of FIG. 2A. According to an example embodiment, at least one of the first horizontal insulating layer 161 or the second horizontal insulating layer 163 may be omitted.

The semiconductor device 100b may include studs 189 disposed between the channel structures CH and the first cell contact plugs 181. The studs 189 may form a second interconnection structure of the second semiconductor structure S2 together with the first cell contact plug 181 and the first cell interconnection lines 182. The studs 189 may be connected to lower ends of the channel structures CH and the first cell contact plugs 181. The studs 189 may include a metal, and may include, for example, tungsten (W), copper (Cu), and aluminum (Al).

As the first lower gate electrode 130L1 is disposed on an upper portion of the first horizontal insulating layer 161 in the first region R1, a first cell contact plug 181a, which is connected to the third cell interconnection line 188 near a boundary between the first region R1 and the third region R3, may be connected to the first lower gate electrode 130L1 through the studs 189. The third and fourth vertical channel structures PCH3 and PCH4 disposed in the third region R3 may form a channel region of a transistor transmitting a gate electrical signal applied to the first lower gate electrode 130L1.

In an example embodiment of FIG. 7B, as compared to the example embodiment of FIG. 2A, a structure of lower ends of the channel structures CH in the first region R1 may be simplified. In the process of forming the first gate electrode 131 and the second gate electrode 133, the same material as these may not be applied to the first region R1. The first gate electrode 131 and the second gate electrode 133 may be disposed regardless of the first lower gate electrode 130L1, and their materials and thicknesses may be different from those of the embodiment of FIG. 2A. According to an example embodiment, the first gate electrode 131 and the second gate electrode 133 may include metal and may be thinner than in the example embodiment of FIG. 2A. Alternatively, each of the first gate electrode 131 and the second gate electrode 133 may be comprise a plurality of metal gate electrodes 131g as in the example embodiment of FIG. 6C.

Referring to FIG. 7C, in a semiconductor device 100c, lower surfaces of the first lower gate electrode 130L1 and the first gate electrode 131 and the second gate electrode 133 may be disposed on different levels. Since the first cell region insulating layer 191 is disposed only in the second region R2 and the third region R3, upper surfaces of the first lower gate electrode 130L1 and the first gate electrode 131 and the second gate electrode 133 may be disposed on different levels. Unlike the example embodiment of FIG. 2A, thicknesses of the first gate electrode 131 and the second gate electrode 133 may be the same as a thickness of the first lower gate electrode 130L1, and lower surfaces thereof may be disposed on different levels.

An example embodiment of FIG. 7C may have a different manufacturing process from the example embodiment of FIG. 2A. In the example embodiment of FIG. 2A, in the process of forming the first lower gate electrode 130L1 described with reference to FIG. 8D below, after applying a gate electrode layer having a uniform thickness on the second horizontal insulating layer 163 and the first cell region insulating layer 191, a chemical mechanical polishing (CMP) process may be performed to polish the gate electrode layer so that an upper surface thereof is planarized. On the other hand, in the example embodiment of FIG. 7C, in the process of forming the first lower gate electrode 130L1, after applying the gate electrode layer having a uniform thickness, a subsequent process may be performed without performing the chemical mechanical polishing process. Accordingly, the first lower gate electrode 130L1 formed in the first region R1 and the first gate electrode 131 and the second gate electrode 133 formed in the second region R2 and the third region R3 respectively may have the same thickness. However, in a subsequent process, for example, a polishing process may be performed to reduce a step portion between the first region R1 and the second and third regions R2 and R3 in the forming process of the third cell region insulating layer 195.

Referring to FIG. 7D, in a semiconductor device 100d, the gate electrodes 130 may extend from the first region R1 to the second region R2 by different lengths to form staircase-shaped step structures in gate pad regions GP. The gate electrodes 130 may have a form of being removed by a predetermined depth from a lower portion of any one of the first to third gate stacked structures GS1, GS2 and GS3 in the gate pad regions GP.

The gate electrodes 130 may form first and second step structures in an asymmetrical shape in the X-direction in each of the gate pad regions GP. The first step structure may be a step structure that is relatively adjacent to the first region R1 and has a lower level in the X-direction, and the second step structure may be a step structure that is relatively distant from the first region R1 and has a higher level in the X-direction. For example, in each of the gate pad regions GP, an inclination of the first step structure may be smaller than an inclination of the second step structure in the first region R1. However, in some example embodiments, the first and second step structures may have a symmetrical shape. In the first step structure, the gate electrodes 130 may be connected to the gate contact plugs 701, and in the second step structure, the gate electrodes 130 may form a dummy region or dummy structure not connected to the gate contact plugs 701.

By the first step structure, the gate electrodes 130 may have end regions exposed upwardly from the interlayer insulating layers 120, respectively, by allowing the lower gate electrode 130 to extend longer than the upper gate electrode 130. The gate electrodes 130 may be respectively connected to the gate contact plugs 701 in the end regions. The gate electrodes 130 may have a form in which a thickness thereof is increased in the end regions. The gate electrodes 130 may include the first region R1, and thus, a thickness thereof in the end regions may be greater than a thickness in a region in which the other gate electrodes 130 are disposed on an upper surface thereof.

The gate contact plugs 701 may be connected to end regions of the gate electrodes 130 in the gate pad regions GP of the second region R2. Unlike the example embodiment of FIG. 2A, the gate contact plugs 701 may penetrate through other gate electrodes 130 above and below the electrically connected gate electrodes 130. The gate contact plugs 701 may be connected to the upper contact structure RMC in lower ends thereof, respectively.

The gate contact plugs 701 may have a shape corresponding to the channel structures CH. Each of the gate contact plugs 701 may have a cylindrical shape whose width increases toward the substrate 201. The upper ends of the gate contact plugs 701 may be disposed on substantially the same level as the upper ends of the channel structures CH, and lower ends of the gate contact plugs 701 may be disposed on substantially the same level as the lower ends of the channel structures CH.

The gate contact plugs 701 may have a shape extending horizontally in the end region of the gate electrode 130. The gate contact plug 701 may include a vertical extension portion extending in the Z-direction and a horizontal extension extending horizontally from the vertical extension portion and contacting the gate electrode 130. The gate contact plug 701 may be electrically separated from the gate electrodes 130 above and below the end regions, i.e., the gate electrodes 130 not connected to the gate contact plug 701, by the gate contact insulating layers 702.

The contact insulating layers 702 may be disposed to surround side surfaces of each of the gate contact plugs 701 above and below each of the end regions. The contact insulating layers 702 may be spaced apart from each other in the Z-direction, around each of the gate contact plugs 701. The contact insulating layers 702 may extend horizontally from side surfaces of each of the gate contact plugs 701 by substantially the same length. The contact insulating layers 702 may be disposed on substantially the same level as the gate electrodes 130, respectively.

FIGS. 8A-8O are schematic cross-sectional views illustrating a method of manufacturing a semiconductor device according to an example embodiment. FIGS. 8A-8O each illustrate cross-sections corresponding to FIG. 2B. FIGS. 8A-8O sequentially illustrate processes after the first horizontal insulating layer 161 is formed in the second semiconductor structure S2 illustrated in FIG. 2B.

Referring to FIG. 8A, gate electrodes 130 and interlayer insulating layers 120 are alternately stacked on a base substrate 101, and channel structures CH, dummy vertical structures DCH, and gate contact structures MC, penetrating through gate electrodes 130 and interlayer insulating layers 120, may be formed, and a first horizontal insulating layer 161 covering the channel structures CH, the dummy vertical structures DCH and the gate contact structures MC may be formed, thereby forming a first molded structure.

The base substrate 101 is a layer removed through a subsequent process, and may be, for example, a semiconductor substrate such as undoped silicon (Si).

The descriptions of the structure of the gate electrodes 130 and interlayer insulating layers 120 alternately stacked on the base substrate 101, the channel structures CH penetrating therethrough, the dummy vertical structures DCH and the gate contact structures MC and the first horizontal insulating layer 161 may be the same as described above with reference to FIGS. 2A and 2B. The first molded structure may also include a first region R1, a second region R2, and a third region R3.

Referring to FIG. 8B, a second horizontal insulating layer 163 and first and second channel connection patterns 171 and 173 may be formed on the first molded structure.

The second horizontal insulating layer 163 may be formed by applying an insulating material layer by a certain thickness on the first horizontal insulating layer 161, and then, forming a material layer forming the first and second channel connection patterns 171 and 173, and then performing a chemical and mechanical polishing process together with the material layer. For example, an insulating material layer forming the second horizontal insulating layer 163 may be applied on the first horizontal insulating layer 161, and then a process of partially etching the insulating material layer in the second region R2 and the third region R3 in which the first and second channel connection patterns 171 and 173 are disposed, and forming an opening exposing the first horizontal insulating layer 161 may be performed.

Then, a material layer forming the first and second channel connection patterns 171 and 173 may be formed on the insulating material layer and the opening. According to an example embodiment, the first and second channel connection patterns 171 and 173 may include polycrystalline silicon, and the material layer may be formed through a deposition and crystallization process of a silicon layer by including polycrystalline silicon. When the material layer is formed to fill the opening of the insulating material layer, the material layer and the insulating material layer may be subjected to a chemical mechanical polishing process together to form a second horizontal insulating layer 163 and first and second channel connection patterns 171 and 173. Among the openings of the insulating material layer, an opening for forming the first channel connection pattern 171 may be formed by corresponding to in a position of the gate contact structures MC in the second region R2.

Referring to FIGS. 8C and 8D, a first cell region insulating layer 191 and a gate electrode layer 130b may be formed on the second horizontal insulating layer 163 and the first and second channel connection patterns 171 and 173.

The first cell region insulating layer 191 may be formed on the second horizontal insulating layer 163 and the first and second channel connection patterns 171 and 173 in the second region R2 and the third region R3. The insulating material layer applied in the formation process of the first cell region insulating layer 191 may insulate the first and second channel connection patterns 171 and 173 and the first and second gate electrodes 131 and 133, and may have a thickness sufficient to secure a channel length of the vertical channel structures PCH1 and PCH2.

The gate electrode layer 130b may be formed on the second horizontal insulating layer 163 and the first cell region insulating layer 191 in the first region R1, the second region R2 and the third region R3. The gate electrode layer 130b may be formed in the first region R1, the second region R2, and the third region R3 with a uniform thickness, and then an upper surface thereof may be planarized through a chemical mechanical polishing process. In the second region R2 and the third region R3, the gate electrode layer 130b has a shape in which an upper surface thereof has a step portion due to the first cell region insulating layer 191, but the upper surface may be planarized through a subsequent polishing process. However, the polishing process for planarizing the upper surface of the gate electrode layer 130b may not necessarily be performed. In the example embodiment of FIG. 7C, the polishing process for planarizing the upper surface of the gate electrode layer 130b may be omitted, so that lower surfaces of the first and second gate electrodes 131 and 133 and the first lower gate electrode 130L1 may be disposed on different levels.

Referring to FIG. 8E, a second cell region insulating layer 193 may be formed on the gate electrode layer 130b, and second and third separation regions US and LS partially separating the gate electrode layer 130b may be formed. The second cell region insulating layer 193 may be formed through a process of applying an insulating material. The second and third separation regions US and LS may be formed by forming a vertical hole penetrating through the second cell region insulating layer 193, the gate electrode layer 130b and the second horizontal insulating layer 163, and then filling an interior thereof with an insulating material. The gate electrode layer 130b may form a first lower gate electrode 130L1 in the first region R1, and may form a first gate electrode 131 and a second gate electrode 133 in the second region R2 and the third region R3, respectively.

Referring to FIG. 8F, in the first region R1, string channel structures SCH extending in the Z-direction by penetrating through the first lower gate electrode 130L1 may be formed. After forming vertical holes penetrating through the second cell region insulating layer 193, the first lower gate electrode 130L1 and the first and second horizontal insulating layers 161 and 163 in the first region R1, string channel structures SCH may be formed within the vertical holes. The vertical holes may be formed in positions corresponding to the channel structures CH, and the string channel structures SCH may be connected to the channel structures CH through the connection pads 150 disposed in the vertical holes formed in the first horizontal insulating layer 161. The string channel structures SCH may include a string channel layer, a string channel dielectric layer, a string channel buried insulating layer and a string channel pad, and each of these may be formed by depositing the same material within the vertical hole.

Referring to FIG. 8G, first through-holes VPT1 penetrating through the first and second cell region insulating layers 191 and 193 and the first and second gate electrodes 131 and 133 may be formed in the second region R2 and the third region R3, and a first insulating layer 144b may be formed on inner sidewalls of the first through-holes VPT1 and the second cell region insulating layer 193.

The first through-holes VPT1 may be formed through a process of etching the first and second cell region insulating layers 191 and 193 and the first and second gate electrodes 131 and 133. The first through-holes VPT1 may be formed in a region overlapping the first and second channel connection patterns 171 and 173, and may expose a portion of an upper surface of the first and second channel connection patterns 171 and 173.

The first insulating layer 144b may be formed by performing a process of applying an insulating material, and may be conformally formed on the inner sidewalls and bottom surfaces of the first through-holes VPT1 and the second cell region insulating layer 193. For example, the first insulating layer 144b may be formed to have a uniform thickness using an atomic layer deposition (ALD) or chemical vapor deposition (CVD) process. The first insulating layer 144b may form a vertical channel dielectric layer 144 of the vertical channel structures PCH.

Referring to FIG. 8H, a portion of the first insulating layer 144b disposed on a bottom surface of the first through-holes VPT1 may be etched to expose a portion of an upper surface of the first and second channel connection patterns 171 and 173. The first insulating layer 144b may be partially removed by performing an etching process substantially identical to an etching process of the first through-holes VPT1. Upper surfaces of the first and second channel connection patterns 171 and 173 may be partially removed by an etching process, and a trench structure may be formed on the upper surfaces thereof.

Referring to FIGS. 8I-8K, a vertical channel layer 142, a vertical channel buried insulating layer 146 and a vertical channel pad 148 may be formed within the first through-holes VPT1 to form vertical channel structures PCH.

First, a process of forming a first material layer 142b included in the vertical channel layer 142 on the first insulating layer 144b may be performed. The first material layer 142b included in the vertical channel layer 142 may be directly applied to an interior of the first through-hole VPT1 and onto the first insulating layer 144b, and may cover the exposed upper surfaces of the first and second channel connection patterns 171 and 173.

Next, a second material layer 146b included in the vertical channel buried insulating layer 146 may be applied onto the first material layer 144b of the vertical channel layer 142, and then, a portion of the second material layer 146b may be removed to form a vertical channel buried insulating layer 146 inside the first through-holes VPT1. A process of partially removing the second material layer 146b may be performed by repeating a chemical mechanical polishing process and an etching process. For example, a portion of the second material layer 146b disposed in a region other than the first through-holes VPT1 may be removed through a chemical mechanical polishing process, and then, a portion disposed inside the first through-holes VPT1 may be partially removed to form a vertical channel buried insulating layer 146. The vertical channel buried insulating layer 146 may fill a space within the first through-holes VPT1 and may be lower in height than the first through-holes VPT1.

Next, a vertical channel pad 148 may be formed on the vertical channel buried insulating layer 146 within the first through-holes VPT1, and a process of removing the first insulating layer 144b and the first and second material layers 142b and 146b disposed in a region other than the first through-holes VPT1 so that the second cell region insulating layer 193 may be exposed may be performed. A process of removing the first insulating layer 144b and the first and second material layers 142b and 146b may be performed through a chemical mechanical polishing process, and the vertical channel pad 148, the vertical channel layer 142, and the vertical channel dielectric layer 144 filling the interior of the first through-holes VPT1 may have upper surfaces coplanar with an upper surface of the second cell region insulating layer 193. In this operation, vertical channel structures PCH may be formed in the second region R2 and the third region R3.

Referring to FIG. 8l, channel connection pads 151a may be formed on the vertical channel structures PCH in the second region R2 and the third region R3. A process of forming the channel connection pads 151a may be similar to the process of forming the first and second channel connection patterns 171 and 173. For example, after applying an insulating material onto the second cell region insulating layer 193, channel connection pads 151a may be formed through a process of forming openings corresponding to the vertical channel structures PCH and applying and polishing a material to fill the openings. According to an example embodiment, the channel connection pads 151a may include polycrystalline silicon and may be formed through a silicon layer application and crystallization process.

Referring to FIG. 8M, second through-holes VPT2 penetrating through the first to third cell region insulating layers 191, 193 and 195, the first gate electrodes 131, the first channel connection pattern 171 and the first horizontal insulating layer 161 in the second region R2 may be formed, and a second insulating layer 704b may be formed on inner sidewalls of the second through-holes VPT2 and the channel connection pads 151a.

The second through-holes VPT2 may be formed in a region corresponding to the gate contact structures MC in the second region R2. The second through-holes VPT2 may be formed to have a diameter smaller than the first channel connection pattern 171 and may expose a portion of an upper surface of the gate contact plug 701. The second through-holes VPT2 may extend so that a portion of an upper surface of the gate contact plug 701 is etched to form a trench.

Before the etching process of forming the second through-holes VPT2, a photoresist layer 900 may be formed on the third cell region insulating layer 195 except for a region in which several vertical channel structures PCH are disposed. A forming process of forming the upper contact plug 703 formed in the second through-holes VPT2 may be performed by a process of depositing a metal material. At that operation, upper pads 159 may be formed together with the upper contact plugs 703, and the photoresist layer 900 may cover a region except for a region in which the upper pads 159 are formed. For example, the photoresist layer 900 may cover a region except for some vertical channel structures PCH in the second region R2 and the third region R3, and the first region R1.

The second insulating layer 704b may be formed by performing a process of applying an insulating material, and may be conformally formed on an inner sidewall and a bottom surface of the second through-holes VPT2, the third cell region insulating layer 195, and the photoresist layer 900. For example, the second insulating layer 704b may be formed to have a uniform thickness using an atomic layer deposition or chemical vapor deposition process. The second insulating layer 704b may form the upper contact insulating layer 704 of the upper contact structure RMC.

Referring to FIG. 8N, a portion of the second insulating layer 704b disposed on a bottom surface of the second through-holes VPT2 may be etched to expose a portion of the upper surface of the gate contact plug 701. In this operation, a trench formed on the upper surface of the gate contact plug 701 may be deeper. Additionally, a portion of the second insulating layer 704b covering the channel connection pad 151a may also be removed, and some of the channel connection pads 151a may be exposed.

Referring to FIG. 8O, an upper contact plug 703 and an upper pad 159 may be formed on some of the second through-holes VPT2 and the channel connection pads 151a. The upper contact plug 703 and the upper pad 159 may be formed by a process of depositing metal, by including metal. The upper contact plug 703 may be surrounded by the upper contact insulating layer 704 while filling the inside of the second through-hole VPT2, and may be connected to the gate contact plug 703. Additionally, the upper contact plug 703 may be formed to extend onto a portion of the channel connection pad 151a disposed in the second region R2, and may be in contact with one of the channel connection pads 151a. The upper pad 159 may be formed on the channel connection pad 151a disposed in the third region R3.

In this operation, while the upper contact plug 703 and the upper pad 159 including metal are formed on the channel connection pads 151a, a silicon-metal compound may be formed on an upper surface of the channel connection pads 151a including polycrystalline silicon. The channel connection pads 151a may be connected to the vertical channel structures PCH to form a source/drain region of a transistor that applies an electric signal to the gate electrodes 130 of the second semiconductor structure S2. When the source/drain region of the transistor is connected to the upper contact plug 703 and the upper pad 159 including metal, a structure in which silicon and metal are stacked with each other may be provided, and a low-resistance metal silicide layer may be formed on an upper surface of the silicon. A transistor including a channel formed by vertical channel structures PCH may be formed so that the source/drain regions are oriented in the same direction, and a low-resistance metal silicide layer may be formed between the silicon and metal layers, thereby having low-resistance element characteristics.

Although not illustrated in the drawing, the second interconnection structures and the second bonding structure illustrated in FIGS. 2A and 2B may be formed on the upper contact plug 703 and the upper pad 159, and the first molded structure may be bonded to the first semiconductor structure S1.

The cell contact plugs 181, 185 and 187 and cell interconnection lines 182, 186 and 188 illustrated in FIG. 2A may be formed on the upper contact structures RMC, upper pads 159 and the third cell region insulating layer 195 of FIG. 8O, thereby forming the second interconnection structures. On the second interconnection structures, second bonding vias 197, second bonding pads 198 and a second bonding insulating layer 199 forming the second bonding structure may be further formed.

The first semiconductor structure S1 may be prepared by forming circuit elements 220 of the peripheral circuit region, the first interconnection structure and the first bonding structure, on the substrate 201. The description of the structure of the first semiconductor structure S1 may be the same as that described above with reference to FIG. 2A.

The first semiconductor structure S1 and the first molded structure may be connected by bonding the first bonding pads 298 and the second bonding pads 198 by annealing and/or pressurizing. At the same time, the first bonding insulating layer 299 and the second bonding insulating layer 199 may also be bonded to each other. The first molded structure may be turned over on the first semiconductor structure S1 so that the second bonding pads 198 face downwardly and the base substrate 101 faces upwardly, and then bonding may be performed. As a result, a bonding stack structure may be formed.

Next, in an upper portion of the bonding stack structure, the base substrate 101 may be removed and a common source layer 105 may be formed.

The base substrate 101 may be partially removed from the upper surface by a grinding process, a portion thereof may be removed by a planarization process such as a chemical mechanical polishing (CMP) process, and the remaining portion may be removed by an etching process such as a wet etching process. Accordingly, upper ends of the channel structures CH may be exposed. In the exposed upper ends of the channel structures CH, the channel dielectric layer 143 may be removed to expose the channel layers 141. The common source layer 105 may be formed to cover the exposed channel layers 141. The semiconductor device 100 may be manufactured by performing the above process.

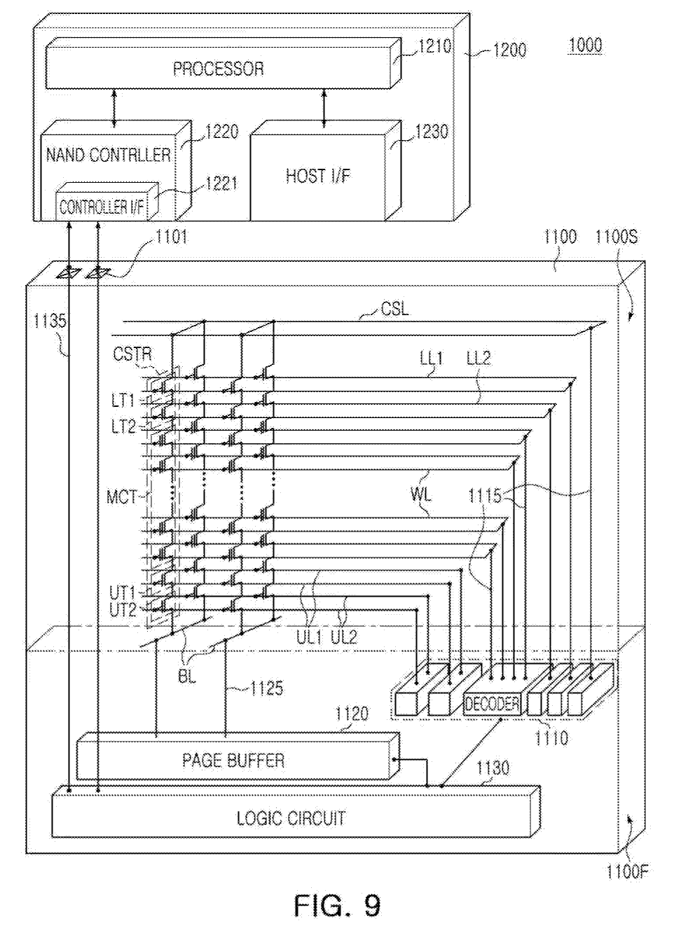

FIG. 9 is a schematic diagram illustrating a data storage system including a semiconductor device according to example embodiments.

Referring to FIG. 9, a data storage system 1000 may include a semiconductor device 1100 and a controller 1200 electrically connected to the semiconductor device 1100. The data storage system 1000 may be a storage device including one or more semiconductor devices 1100 or an electronic device including the storage device. For example, the data storage system 1000 may be a solid state drive device (SSD), a Universal Serial Bus (USB), a computing system, a medical device, or a communication device including one or more semiconductor devices 1100.

The semiconductor device 1100 may be a nonvolatile memory device, and may be, for example, a NAND flash memory device described above with reference to FIGS. 1-7D. The semiconductor device 1100 may include a first structure 1100F and a second structure 1100S on the first structure 1100F. In example embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1, LL2, and memory cell strings CSTR between the bit line BL and the common source line CSL.

In the second structure 1100S, each memory cell string CSTR may include upper transistors UT1 and UT2 adjacent to the common source line CSL, lower transistors LT1 and LT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously changed according to example embodiments.

In example embodiments, the upper transistors UT1 and UT2 may include string select transistors, and the lower transistors LT1 and LT2 may include ground select transistors. The gate lower lines LL1, LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In example embodiments, the lower transistors LT1 and LT2 may include a lower erase control transistor LT1 and a ground select transistor LT2 which are serially connected. The upper transistors UT1 and UT2 may include a string select transistor UT1 and an upper erase control transistor UT2 serially connected. At least one of the lower erase control transistor LT1 or the upper erase control transistor UT2 may be used for an erase operation of erasing data stored in the memory cell transistors MCT by utilizing a Gate Induced Drain Leakage (GIDL) phenomenon.

The common source line CSL, the first and second gate lower lines LL1, LL2, the word lines WL and the first and second gate upper lines UL1 and UL2 may be electrically connected to the decoder circuit 1110 through first interconnection lines 1115 extending from the first structure 1100F to the second structure 1100S. The bit lines BL may be electrically connected to the page buffer 1120 through second interconnection lines 1125 extending from the first structure 1100F to the second structure 1100S.

In the first structure 1100F, the decoder circuit 1110 and the page buffer 1120 may execute a control operation for at least one selected memory cell transistor, among a plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through input/output interconnection lines 1135 extending from the first structure 1100F to the second structure 1100S.

The controller 1200 may include a processor 1210, a NAND controller 1220, and a host interface 1230. According to example embodiments, the data storage system 1000 may include a plurality of semiconductor devices 1100, and in this case, the controller 1200 may control the plurality of semiconductor devices 1100.

The processor 1210 may control an overall operation of the data storage system 1000 including the controller 1200. The processor 1210 may operate according to a predetermined firmware, and may control the NAND controller 1220 to access the semiconductor device 1100. The NAND controller 1220 may include a controller interface 1221 processing communication with the semiconductor device 1100. Through the controller interface 1221, control commands for controlling the semiconductor device 1100, data to be written to the memory cell transistors MCT of the semiconductor device 1100, data to be read from the memory cell transistors MCT of the semiconductor device 1100, and the like, may be transmitted. The host interface 1230 may provide a communication function between the data storage system 1000 and an external host. When a control command is received from the external host through the host interface 1230, the processor 1210 may control the semiconductor device 1100 in response to the control command.

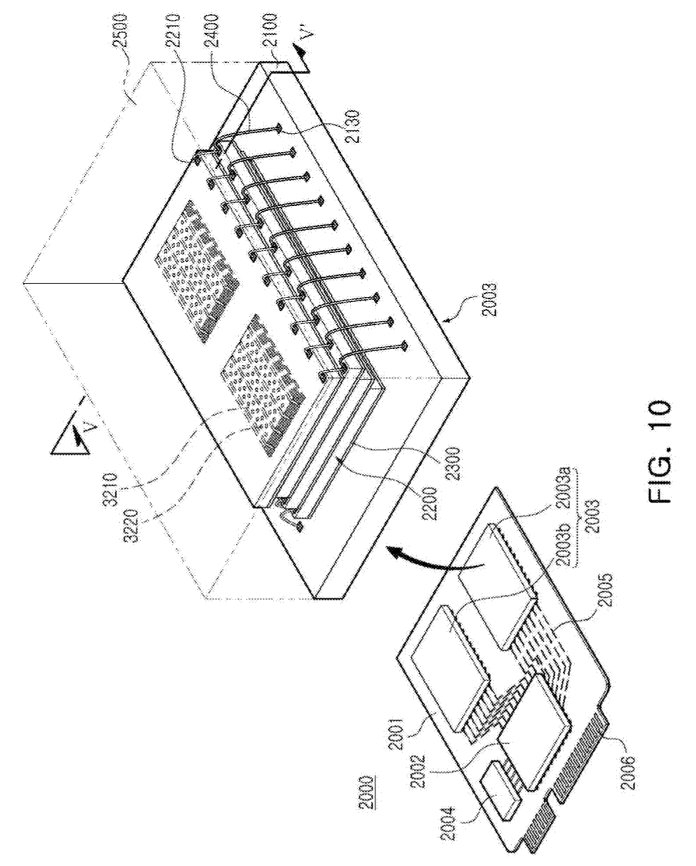

FIG. 10 is a perspective view schematically illustrating a data storage system including a semiconductor device according to an example embodiment.

Referring to FIG. 10, a data storage system 2000 according to an example embodiment of the present disclosure may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to the external host. The number and arrangement of the plurality of pins in the connector 2006 may vary depending on a communication interface between the data storage system 2000 and the external host. In example embodiments, the data storage system 2000 may communicate with the external host according to any one of interfaces, such as Universal Serial Bus (USB), Peripheral Component Interconnect Express (PCI-Express), Serial Advanced Technology Attachment (SATA), and M-Phy for Universal Flash Storage (UFS). In example embodiments, the data storage system 2000 may operate by power supplied from the external host through the connector 2006. The data storage system 2000 may further include a Power Management Integrated Circuit (PMIC) distributing the power supplied from the external host to the controller 2002 and the semiconductor package 2003.

The controller 2002 may write data to the semiconductor package 2003 or read data from the semiconductor package 2003, and may improve the operating speed of the data storage system 2000.

The DRAM 2004 may be a buffer memory for mitigating a speed difference between the semiconductor package 2003, which is a data storage space, and the external host. The DRAM 2004 included in the data storage system 2000 may also function as a kind of cache memory, and may also provide a space for temporarily storing data in a control operation for the semiconductor package 2003. When the DRAM 2004 is included in the data storage system 2000, the controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each semiconductor chip 2200 may include an input/output pad 2210. The input/output pad 2210 may correspond to the input/output pad 1101 of FIG. 9. Each of the semiconductor chips 2200 may include gate stack structures 3210 and channel structures 3220. Each of the semiconductor chips 2200 may include the semiconductor device described above with reference to FIGS. 1-7D.

In example embodiments, the connection structure 2400 may be a bonding wire that electrically connects the input/output pad 2210 and the package upper pads 2130. Accordingly, in each of the first and second semiconductor packages 2003a and 2003b, the semiconductor chips 2200 may be electrically connected to each other in a bonding wire manner, and may be electrically connected to the package upper pads 2130 of the package substrate 2100. According to example embodiments, in each of the first and second semiconductor packages 2003a and 2003b, the semiconductor chips 2200 may be electrically connected to each other by a connecting structure including a through-silicon via (TSV), instead of a connecting structure 2400 in a bonding wire manner.

In example embodiments, the controller 2002 and the semiconductor chips 2200 may be included in one package. In an example embodiment, the controller 2002 and the semiconductor chips 2200 may be mounted on a separate interposer substrate different from a main substrate 2001, and the controller 2002 and semiconductor chips 2200 may be connected to each other by interconnection lines formed on the interposer substrate.

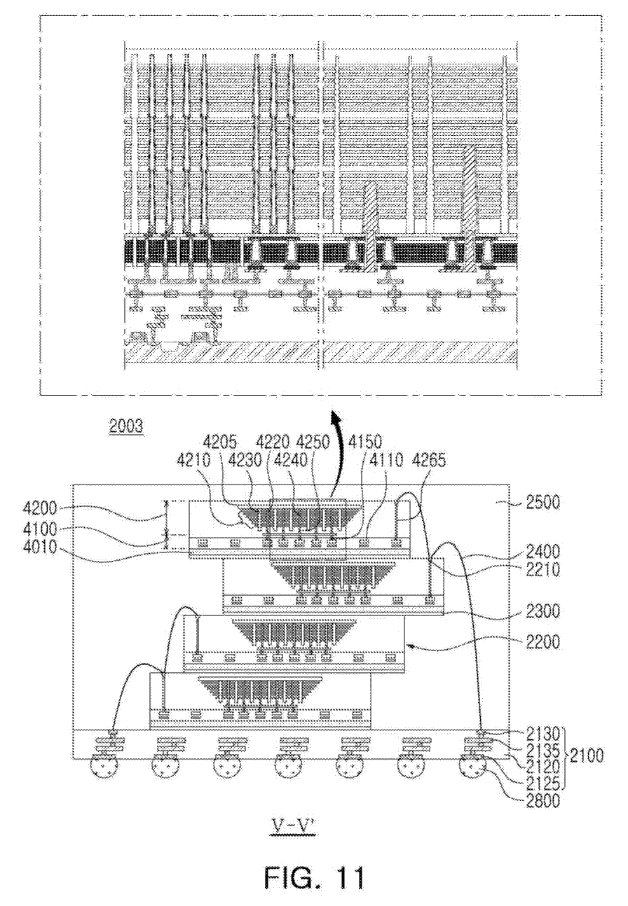

FIG. 11 is a cross-sectional view schematically illustrating a semiconductor package according to an example embodiment. FIG. 11 describes an example embodiment of a semiconductor package 2003 of FIG. 10, and conceptually illustrates a region taken along a cutting line V-V' of the semiconductor package 2003 of FIG. 10.

Referring to FIG. 11, in the semiconductor package 2003, the package substrate 2100 may be a printed circuit board. The package substrate 2100 may include a package substrate body 2120, package upper pads 2130 disposed on an upper surface of the package substrate body 2120, lower pads 2125 disposed on a lower surface of the package substrate body 2120 or exposed through the lower surface, and internal interconnection lines 2135 electrically connecting the upper pads 2130 and the lower pads 2125 within the package substrate body 2120. The upper pads 2130 may be electrically connected to the connecting structures 2400. The lower pads 2125 may be connected to the interconnection patterns 2005 of the main substrate 2001 of the electronic system 2000 as illustrated in FIG. 11 through conductive connecting portions 2800.

Each of the semiconductor chips 2200a may include a semiconductor substrate 4010, a first structure 4100 on the semiconductor substrate 4010, and a second structure 4200 bonded to the first structure 4100 by a wafer bonding method on the first structure 4100. The first structure 4100 is illustrated as being packaged to be disposed in a lower portion, unlike in FIG. 2A, but the present disclosure is not limited thereto.

The first structure 4100 may include a peripheral circuit region including peripheral interconnection lines 4110 and first bonding structures 4150. The second structure 4200 may include a common source line 4205, a gate stack structure 4210, channel structures 4220 and a separation region 4230 penetrating through the gate stack structure 4210, and second bonding structures 4250 electrically connected to the memory channel structures 4220 and the word lines WL (see FIG. 11) of the gate stack structure 4210, respectively. For example, the second bonding structures 4250 may be electrically connected to the memory channel structures 4220 and the word lines WL, respectively, through separate gate contacts electrically connected to bit lines 4240 and the word lines WL electrically connected to the memory channel structures 4220. The first bonding structures 4150 of the first structure 4100 and the second bonding structures 4250 of the second structure 4200 may be in contact with and bonded to each other. The bonded portions of the first bonding structures 4150 and the second bonding structures 4250 may be formed of, for example, copper (Cu).

The second structure 4200 may include first and second vertical channel structures PCH1 and PCH2 disposed on upper portions of the gate contact structures MC, as illustrated in the enlarged view, and a transistor applying an electric signal to the gate contact structures MC may be disposed on the second semiconductor structure S2. Each of the semiconductor chips 2200a may further include an input/output pad 2210 and an input/output interconnection line 4265 below the input/output pad 2210. The input/output interconnection line 4265 may be electrically connected to some of the second bonding structures 4210.

The semiconductor chips 2200a may be electrically connected to each other by connection structures 2400 in the form of bonding wires. However, in example embodiments, semiconductor chips within a single semiconductor package, such as semiconductor chips 2200a, may be electrically connected to each other by a connecting structure including a through-silicon via (TSV).

A method of manufacturing a semiconductor device according to example embodiments may include: forming a first molded structure by forming interlayer insulating layers and gate electrodes alternately stacked on a base substrate, channel structures and gate contact structures penetrating through the interlayer insulating layers and the gate electrodes and extending in a first direction, perpendicular to an upper surface of the base substrate, and a first horizontal insulating layer covering upper ends of the channel structures and the gate contact structures; forming a second horizontal insulating layer on the first horizontal insulating layer, and forming channel connection patterns in a region overlapping the gate contact structures, among the second horizontal insulating layers; forming a first cell region insulating layer covering the channel connection patterns, and forming a first gate electrode and a first lower gate electrode on the second horizontal insulating layer and the first cell region insulating layer; forming first through-holes penetrating through the first gate electrode and the first cell region insulating layer and overlapping the channel connection pattern; forming vertical channel structures in the first through-holes, and forming channel connection pads on the vertical channel structures; forming second through-holes penetrating through the first gate electrode, the first cell region insulating layer and the channel connection pattern and overlapping the gate contact structure; forming upper contact plugs in the second through-holes; forming a second interconnection structure including cell contact plugs and cell interconnection lines, and second bonding pads, on the channel structures, the upper contact plugs and the channel connection pads; preparing a first semiconductor structure including a substrate, circuit elements on the substrate, a first interconnection structure electrically connected to the circuit elements, and first bonding pads on the first interconnection structure; forming a second bonding stack structure by bonding the first molded structure and the first semiconductor structure so that the first bonding pads and the second bonding pads are connected to each other; removing the base substrate on the second bonding stack structure and exposing ends of the channel structures; and forming a common source layer on ends of the channel structures.

In a method of manufacturing a semiconductor device according to an example embodiment, the upper contact plug may include a portion disposed on the channel connection pad and in contact with the channel connection pad, and in the forming the upper contact plug, a metal silicide layer may be formed on a portion in which the upper contact plug and the channel connection pad are in contact with each other.

In a method of manufacturing a semiconductor device according to an example embodiment, some of the cell contact plugs of the second interconnection structure may be connected to the channel connection pad.

In a method of manufacturing a semiconductor device according to an example embodiment, the forming the upper contact plug may include: forming an upper contact insulating layer on an inner sidewall and a bottom surface of the second through-holes; etching and removing a portion of the upper contact insulating layer disposed on the bottom surface of the second through-hole; and forming the upper contact plug inside the second through-hole.

In a method of manufacturing a semiconductor device according to an example embodiment, a portion of the upper contact insulating layer may be disposed between the upper contact plug and the channel connection pattern.

In a method of manufacturing a semiconductor device according to an example embodiment, the vertical channel structure may include: a vertical channel buried insulating layer disposed within the first through-hole; a vertical channel layer surrounding the vertical channel buried insulating layer and connected to the channel connection pattern; a vertical channel dielectric layer surrounding the vertical channel layer and disposed between the vertical channel layer and the first gate electrode; and a vertical channel pad disposed on the vertical channel buried insulating layer and connected to the channel connection pad.

In a method of manufacturing a semiconductor device according to an example embodiment, in the forming the first through-hole, a portion of an upper surface of the channel connection pad may be etched, and the vertical channel layer of the vertical channel structure may be in contact with an etched upper surface in a forming process of the first through-hole, among the upper surfaces of the channel connection pad.

In a method of manufacturing a semiconductor device according to an example embodiment, the vertical channel layer may be formed to surround a side surface of the vertical channel pad, and upper ends of the vertical channel layer, the vertical channel pad and the vertical channel dielectric layer may form a coplanar surface.

In a method of manufacturing a semiconductor device according to an example embodiment, the forming the first gate electrode and the first lower gate electrode may include: forming a gate electrode layer disposed on the first cell region insulating layer and the second horizontal insulating layer; and planarizing an upper surface of the gate electrode layer, and a thickness of the first gate electrode may be smaller than the thickness of the first lower gate electrode.

In a method of manufacturing a semiconductor device according to an example embodiment, the first cell region insulating layer may not overlap the channel structures.

The present disclosure is not limited to the above-described embodiments and the accompanying drawings but is defined by the appended claims. Therefore, those of ordinary skill in the art may make various replacements, modifications, or changes, and combinations of example embodiments without departing from the scope of the present disclosure defined by the appended claims, and these replacements, modifications, or changes should be construed as being included in the scope of the present disclosure.

What is claimed is:

1. A semiconductor device, comprising:
a first semiconductor structure including a substrate, circuit elements disposed on the substrate, a first interconnection structure disposed on the circuit elements, and first bonding pads disposed on the first interconnection structure; and
a second semiconductor structure disposed on the first semiconductor structure and including a first region and a second region disposed in one end of the first region in the first direction,
wherein the second semiconductor structure includes:
gate electrodes stacked and spaced apart from each other in a second direction, perpendicular to an upper surface of the substrate;
interlayer insulating layers alternately stacked with the gate electrodes;
channel structures penetrating through at least a portion of the gate electrodes in the first region and extending in the second direction, wherein each of the channel structures includes a channel layer;
gate contact structures penetrating through at least a portion of the gate electrodes in the second region and extending in the second direction, wherein each of the gate contact structures is electrically connected to the portion of the gate electrodes in the second region;
a common source layer covering upper ends of the channel structures and in contact with the channel layer;
first channel connection patterns disposed below lower ends of the gate contact structures in the second region;
vertical channel structures penetrating through a first gate electrode disposed below the first channel connection patterns among the gate electrodes, and vertical channel structures extending in the second direction;
channel connection pads below the vertical channel structures;
upper contact structures penetrating through the first gate electrode and the first channel connection patterns, the upper contact structures extending in the second direction and connected to the gate contact structures;
second interconnection structures including cell interconnection lines electrically connected to the channel structures or the channel connection pads, the second interconnection structures disposed below lower ends of the channel structures and the channel connection pads; and
second bonding pads disposed below the second interconnection structures and connected to the first bonding pads,
wherein the vertical channel structures include first vertical channel structures in which first ends thereof in the second direction are connected to the first channel connection patterns, and second vertical channel structures connected to the first vertical channel structures through the first channel connection patterns, and
wherein second ends of the first vertical channel structures opposite to the first ends in the second direction, are connected to the upper contact structures.

2. The semiconductor device of claim 1, wherein each of the upper contact structures include an upper contact plug and an upper contact insulating layer surrounding a side surface of the upper contact plug, and
wherein the upper contact plug is connected to one of the channel connection pads and the gate contact structure.

3. The semiconductor device of claim 1, wherein the gate electrodes further include:
a first lower gate electrode spaced apart from the first gate electrode in the first direction below the channel structures in the first region; and
a first cell region insulating layer disposed between the first gate electrode and the first channel connection patterns in the second region.

4. The semiconductor device of claim 3, further comprising:
string channel structures penetrating through the first lower gate electrode and extending in the second direction, the string channel structures connected to lower ends of the channel structures, and
wherein a maximum diameter of the vertical channel structures is greater than a maximum diameter of the string channel structures.

5. The semiconductor device of claim 3, wherein a lower surface of the first lower gate electrode is disposed on a same level as a lower surface of the first gate electrode, and a thickness of the first lower gate electrode is greater than a thickness of the first gate electrode.

6. The semiconductor device of claim 3, wherein a lower surface of the first lower gate electrode is disposed on a different level from a lower surface of the first gate electrode, and a thickness of the first lower gate electrode is same with a thickness of the first gate electrode.

7. The semiconductor device of claim 3, wherein the second semiconductor structure includes:
a third region disposed between the first region and the second region;
a second gate electrode disposed on the same level as the first gate electrode in the third region;
a plurality of third vertical channel structures and a plurality of fourth vertical channel structures penetrating through the second gate electrode and extending in the second direction; and
a second channel connection pattern connected to third ends of each of the plurality of third vertical channel structures and the plurality of fourth vertical channel structures in the second direction,
wherein the plurality of third vertical channel structures are electrically connected to the first lower gate electrode through the cell interconnection lines.

8. The semiconductor device of claim 1, wherein the channel connection pads include first channel connection pads disposed corresponding to the first vertical channel structures, and second channel connection pads disposed corresponding to the second vertical channel structures.

9. The semiconductor device of claim 1, wherein each of the first vertical channel structures and the second vertical channel structures includes:
a vertical channel layer extending in the second direction;
a vertical channel buried insulating layer surrounded by the vertical channel layer;
a vertical channel dielectric layer surrounding the vertical channel layer; and
a vertical channel pad disposed at least on one end of the vertical channel layer in the second direction,
wherein the vertical channel pad is connected to the channel connection pads.

10. The semiconductor device of claim 9, wherein the vertical channel pad of each of the first vertical channel structures and the second vertical channel structures includes a first vertical channel pad disposed adjacent to the channel connection pads, and a second vertical channel pad disposed adjacent to the first channel connection patterns.

11. The semiconductor device of claim 9, wherein a portion of the vertical channel layer of each of the first vertical channel structures and the second vertical channel structures is disposed between one surface of the vertical channel buried insulating layer in the second direction and the first channel connection patterns.

12. The semiconductor device of claim 9, wherein the vertical channel layer of each of the first vertical channel structures and the second vertical channel structures surrounds a side surface of the vertical channel buried insulating layer, and the vertical channel buried insulating layer is in contact with the first channel connection pattern.

13. The semiconductor device of claim 1, wherein the first gate electrode is comprised of a plurality of metal gate electrodes including a metal.

14. A semiconductor device, comprising:
gate electrodes stacked and spaced apart from each other in a first direction, perpendicular to an upper surface of a substrate;
channel structures penetrating through the gate electrodes and extending in the first direction, wherein each of the channel structures respectively includes a channel layer;
gate contact plugs extending in the first direction and electrically connected to the gate electrodes, respectively;
vertical channel structures penetrating through a first gate electrode disposed below a lower end of the gate contact plugs, among the gate electrodes, and extending in the first direction, wherein each of the vertical channel structures respectively includes a vertical channel layer;
channel connection patterns disposed on the first gate electrode and in contact with first ends of the vertical channel structures in the first direction;
channel connection pads disposed below the first gate electrode and in contact with second ends of the vertical channel structures in the first direction, the channel connection pads including a first channel connection pad and a second channel connection pad which are spaced apart from each other; and
upper contact plugs penetrating through the first gate electrode and extending in the first direction, the upper contact plugs electrically connected to the gate contact plugs, respectively.

15. The semiconductor device of claim 14, wherein each of the first channel connection pad and the second channel connection pad is connected to one or more of the vertical channel structures different from each other.

16. The semiconductor device of claim 15, wherein the first ends of the vertical channel structures connected to the first channel connection pad and the first ends of the vertical channel structures connected to the second channel connection pad are in contact with a first channel connection pattern among the channel connection patterns.

17. The semiconductor device of claim 14, wherein one of the upper contact plugs is connected to the first channel connection pad.

18. The semiconductor device of claim 14, further comprising:
a contact plug in contact with the first gate electrode.

19. A data storage system, comprising:
a semiconductor storage device including a first semiconductor structure including circuit elements, a second semiconductor structure disposed on the first semiconductor structure, and an input/output pad electrically connected to the circuit elements; and
a controller electrically connected to the semiconductor storage device through the input/output pad and configured to control the semiconductor storage device,
wherein the second semiconductor structure includes:
gate electrodes stacked and spaced apart from each other in a first direction, perpendicular to an upper surface of the first semiconductor structure;
channel structures penetrating through the gate electrodes and extending in the first direction, wherein each of the channel structures respectively includes a channel layer;
gate contact plugs extending in the first direction and electrically connected to the gate electrodes;
vertical channel structures penetrating through a first gate electrode disposed below a lower end of the gate contact plug, among the gate electrodes, and extending in the first direction, wherein each of the vertical channel structures respectively includes a vertical channel layer;
channel connection patterns disposed on the first gate electrode and in contact with first ends of the vertical channel structures in the first direction;
channel connection pads disposed below the first gate electrode and in contact with second ends of the vertical channel structures in the first direction; and
upper contact plugs penetrating through the first gate electrode and extending in the first direction, and electrically connected to the gate contact plugs, respectively,
wherein each of the vertical channel structures includes a vertical channel buried insulating layer surrounded by the vertical channel layer, a vertical channel dielectric layer surrounding the vertical channel layer, and a vertical channel pad adjacent to the second end of the vertical channel structure and in contact with the vertical channel buried insulating layer.

20. The data storage system of claim 19, wherein at least one of the channel connection pads is in contact with the upper contact plugs and each of the vertical channel structures.
